(19) United States
(12) Patent Application Publication
(10) Pub. No.: US 2013/0118573 A1
(43) Pub. Date: May 16, 2013

(54) PASTE COMPOSITION FOR ELECTRODE, PHOTOVOLTAIC CELL ELEMENT, AND PHOTOVOLTAIC CELL

(71) Applicant: Hitachi Chemical Company, Ltd., Tokyo (JP)

(72) Inventors: Shuichiro ADACHI, Tsukuba-shi (JP); Masato YOSHIDA, Tsukuba-shi (JP); Takeshi NOJIRI, Tsukuba-shi (JP); Yoshiaki KURIHARA, Tsukuba-shi (JP); Takahiko KATO, Hitachi-shi (JP)

(73) Assignee: HITACHI CHEMICAL COMPANY, LTD., Tokyo (JP)

(21) Appl. No.: 13/675,742

(22) Filed: Nov. 13, 2012

Related U.S. Application Data
(60) Provisional application No. 61/559,598, filed on Nov. 14, 2011.

(51) Int. Cl. H01B 1/02; H01L 31/0224

(52) U.S. Cl. CPC H01B 1/026; H01L 31/022425
USPC 136/256; 252/513

(57) ABSTRACT

The present invention provides a paste composition for an electrode comprising a phosphorus-containing copper alloy particle, a tin-containing particle, a nickel-containing particle, a glass particle, a solvent, and a resin.

### CROSS-REFERENCE TO RELATED APPLICATIONS

This application claims priority under 35 U.S.C. 119(e) to Provisional U.S. Patent Application No. 61/559,598, filed Nov. 14, 2011, the disclosures of which are incorporated by reference herein.

### BACKGROUND OF THE INVENTION

1. Field of the Invention

The present invention relates to a paste composition for an electrode, a photovoltaic cell element, and a photovoltaic cell.

2. Description of the Related Art

Generally on a light receiving surface and a back surface of a silicon based photovoltaic cell, electrodes are formed. In order to output efficiently the electrical energy converted in a photovoltaic cell from incident light, it is necessary that the electrodes have sufficiently low volume resistivity and form a good ohmic contact with the silicon substrate. Especially there is a tendency for an electrode on the light receiving surface to have a thin electrode width and a high electrode aspect ratio, in order to limit the incidence loss of sunlight to the minimum.

An electrode used on a light receiving surface of a photovoltaic cell is usually formed as follows. Namely, a texture (asperity) is formed on the light receiving surface side of a p-type silicon substrate; then by diffusing thermally phosphorus or the like at a high temperature to form an n-type silicon layer, on which a conductive composition is provided by screen printing or the like, followed by sintering in the atmosphere at 800° C. to 900° C. to form a light receiving surface electrode. The conductive composition for forming a light receiving surface electrode contains a conductive metal powder, a glass particle, and various additives.

As the conductive metal powder, usually a silver powder is used. The reasons thereof include: the volume resistivity of a silver particle is as low as 1.6×10⁻⁶ Ω·cm; a silver particle can be sintered under the sintering condition through auto-reduction; a good ohmic contact with a silicon substrate can be established; and the wettability of a solder material to an electrode made of a silver particle is superior, so that wiring materials such as a tab wire connecting electrically photovoltaic cell elements each other in forming a module system encapsulating photovoltaic cell elements with a glass substrate or the like can be well bonded.

As described above, a conductive composition containing a silver particle exhibits good characteristics as an electrode for a photovoltaic cell. Meanwhile, since silver is a noble metal and the base metal itself is expensive, and in perspective of a resource issue, a proposal of a conductive composition replacing a silver-containing conductive composition has been desired. Examples of a promising material replacing silver include a copper, which is utilized as a semiconductor wiring material. Copper is abundant in terms of resources and the cost of the base metal is approx. hundredth as low as silver. However, copper is a material easily oxidize at a high temperature of 200° C. or higher in the atmosphere and consequently it is difficult to form an electrode according to the above described process.

To eliminate such a drawback of copper, disclosed is a copper particle which is hard to be oxidized by a high temperature sintering through imparting oxidation resistance to copper by means of various techniques (For example, see Japanese Patent Laid-Open (JP-A) No. 2005-314755 and JP-A No. 2004-217952).

### SUMMARY OF THE INVENTION

However, the oxidation resistance of the copper particles is limited to 300° C. at most and at a temperature as high as 800° C. to 900° C. substantially all of them are oxidized, and consequently they have been not yet commercialized as a photovoltaic cell electrode. Further, since additives and the like added for imparting oxidation resistance disturb sintering of copper particles during sintering, there is consequently a problem that an electrode with such low volume resistivity as silver cannot be obtained.

There is another special process, by which a conductive composition using copper as a conductive metal powder is sintered in the atmosphere of nitrogen or the like for suppressing oxidization of copper.

When the above technique is applied, however, in order to suppress completely the oxidization of a copper particle, an environment sealed completely by the atmospheric gas is required, which is not suitable for mass production of a photovoltaic cell element from a perspective of a processing cost.

There is another problem in a property of an ohmic contact with a silicon substrate for applying copper to a photovoltaic cell electrode. Namely, even if an electrode composed of copper can be formed without causing oxidation during high temperature sintering, by direct contact between copper and a silicon substrate interdiffusion of copper and silicon may take place and a reactant phase (Cu₃Si) composed of copper and silicon may be occasionally formed on the interface of an electrode and a silicon substrate.

The formed Cu₃Si may occasionally reach the depth of several μm from the interface and sometimes cause a crack on the silicon substrate side. Further, in some cases it may penetrate through an n-type silicon layer formed previously on the silicon substrate deteriorating the semiconductor performance (pn-junction property) of the photovoltaic cell. Further, the formed Cu₃Si may lift up an electrode made of copper suppressing the adhesion with the silicon substrate and decreasing the mechanical strength of the electrode.

The present invention was made in view of the problems with an object to provide a paste composition for an electrode, which can form an electrode with low resistivity, and further form a copper-containing electrode having a good ohmic contact with the silicon substrate, as well as a photovoltaic cell element and a photovoltaic cell having an electrode formed with the paste composition for an electrode.

To accomplish the object the inventors studied intensively to complete the present invention. More particularly, the present invention is as follows.

The 1st aspect of the present invention is a paste composition for an electrode comprising a phosphorus-containing copper alloy particle, a tin-containing particle, a nickel-containing particle, a glass particle, a solvent, and a resin.

With respect to the paste composition for an electrode, the phosphorus content of the phosphorus-containing copper alloy particle is preferably from 6% by mass to 8% by mass.

The tin-containing particle is preferably at least one selected from the group consisting of a tin particle and a tin alloy particle having a tin content of 1% by mass or more.

The nickel-containing particle is preferably at least one selected from the group consisting of a nickel particle and a nickel alloy particle having a nickel content of 1% by mass or more.

The glass particle has preferably a glass softening point of 650° C. or less and a crystallization initiation temperature of more than 650° C.

With respect to the paste composition for an electrode, the content of the tin-containing particle is preferably from 5% by mass to 70% by mass when the total content of the phosphorus-containing copper alloy particle, the tin-containing particle and the nickel-containing particle is 100% by mass.

With respect to the paste composition for an electrode, the content of the nickel-containing particle is preferably from 10% by mass to 60% by mass when the total content of the phosphorus-containing copper alloy particle, the tin-containing particle and the nickel-containing particle is 100% by mass.

With respect to the paste composition for an electrode, the total content of the phosphorus-containing copper alloy particle, the tin-containing particle, and the nickel-containing particle is preferably from 70% by mass to 94% by mass, the content of the glass particle is preferably from 0.1% by mass to 10% by mass, and the total content of the solvent and the resin is preferably from 3% by mass to 29.9% by mass.

The paste composition for an electrode preferably comprises further a silver particle, and more preferably the content of the silver particle is from 0.1% by mass to 10% by mass when the total content of the phosphorus-containing copper alloy particle, the tin-containing particle, the nickel-containing particle, and the silver particle is 100% by mass.

With respect to the paste composition for an electrode, preferably the total content of the phosphorus-containing copper alloy particle, the tin-containing particle, the nickel-containing particle, and the silver particle is from 70% by mass to 94% by mass, the content of the glass particle is from 0.1% by mass to 10% by mass, and the total content of the solvent and the resin is from 3% by mass to 29.9% by mass.

The 2nd aspect of the present invention is a photovoltaic cell element, comprising a silicon substrate having a pn-junction and an electrode that is a sintering material of the paste composition for an electrode that has been applied on to the silicon substrate.

The electrode comprises preferably a Cu—Sn—Ni alloy phase and an Sn—P—O glass phase, and more preferably the Sn—P—O glass phase is disposed between the Cu—Sn—Ni alloy phase and the silicon substrate.

The 3rd aspect of the present invention is a photovoltaic cell, comprising the photovoltaic cell element and a wiring material disposed on the electrode of the photovoltaic cell element.

According to the present invention a paste composition for an electrode, which can form an electrode with low resistivity, and further form a copper-containing electrode having a good ohmic contact with the silicon substrate, as well as a photovoltaic cell element and a photovoltaic cell having an electrode formed with the paste composition for an electrode can be provided.

### BRIEF DESCRIPTION OF THE DRAWINGS

FIG. 1 is a schematic cross-sectional view showing an example of a silicon photovoltaic cell element according to the present invention.

FIG. 2 is a schematic plan view showing an example of a light receiving surface of a silicon photovoltaic cell element according to the present invention.

FIG. 3 is a schematic plan view showing an example of a back surface of a silicon photovoltaic cell element according to the present invention.

FIG. 4 is a schematic plan view showing an example of a back surface-side electrode structure of a back-contact type photovoltaic cell element according to the present invention.

FIG. 5 is a schematic perspective view showing an example of an AA cross-section constitution of a back-contact type photovoltaic cell element according to the present invention.

FIG. 6 is a schematic perspective view showing an example of an AA cross-section constitution of a back-contact type photovoltaic cell element according to the present invention.

FIG. 7 is a schematic perspective view showing an example of an AA cross-section constitution of a back-contact type photovoltaic cell element according to the present invention.

### DETAILED DESCRIPTION OF THE INVENTION

The term “step” as used herein encompasses not only an independent step but also a step in which the anticipated effect of this step is achieved, even if the step cannot be clearly distinguished from another step. In addition, a numerical value range indicated by use of the term “to” as used herein refers to a range including the numerical values described before and after “to” as the minimum and maximum values, respectively. Unless specifically indicated, in a case in which each ingredient of a composition includes plural materials, the content of each ingredient of the composition denotes the total amount of the plural materials included in the composition.

<Paste Composition for Electrode>

A paste composition for an electrode according to the present invention contains at least one phosphorus-containing copper alloy particle, at least one tin-containing particle, at least one nickel-containing particle, at least one glass particle, at least one solvent, and at least one resin. By virtue of such constitution oxidation of copper during sintering in the atmosphere is suppressed and an electrode with low resistivity can be formed. Further, formation of a reactant phase of copper and a silicon substrate is suppressed and a good ohmic contact between a formed electrode and the silicon substrate can be established. This is regarded, for example, as follows.

Firstly, when the paste composition for an electrode is subjected to a sintering treatment, a Cu—Sn alloy phase and a Sn—P—O glass phase are formed by a reaction between the phosphorus-containing copper alloy particle and tin-containing particle. By the formation of the Cu—Sn alloy phase, an electrode with low volume resistivity can be formed. Here, since the Cu—Sn alloy phase is formed at a relatively low temperature as low as about 500° C., sintering of an electrode at a low temperature becomes possible, by which reduction in process cost can be expected. The paste composition for an electrode further contains nickel-containing particle. As the result, it is considered that the Cu—Sn alloy phase and the nickel-containing particle further react each other to form a Cu—Sn—Ni alloy phase. Since the Cu—Sn—Ni alloy phase is also formed at a relatively high temperature as high as 800° C., it is considered that an electrode with volume resistivity can be formed, while maintaining the oxidation resistance even in a sintering process at a higher temperature. Namely, use of the paste composition for an electrode can responds to a variety of conditions such as sintering an electrode at a low temperature to a high temperature. Accordingly, the paste composition for an electrode can be widely used as an electrode material for photovoltaic cells with the below-mentioned various structures.

The above Cu—Sn—Ni alloy phase forms a compact bulk in the electrode between Cu—Sn—Ni alloy phases or together with a Cu—Sn alloy phase which is further formed corresponding to a sintering condition, which functions as a conductive layer to form an electrode with low resistivity. It is thought that coexistence of the Cu—Sn alloy phase and the Cu—Sn—Ni alloy phase in the electrode does not decrease functions (for example, low volume resistivity). A compact bulk herein means a three-dimensional continuous structure constituted by massive Cu—Sn alloy phases and Cu—Sn—Ni alloy phases contacting each other compactly.

Further, in cases where an electrode is formed using a paste composition for an electrode on a substrate containing silicon (hereinafter also referred to simply as “silicon substrate”), an electrode with high adhesion to the silicon substrate can be formed, and a good ohmic contact between the electrode and the silicon substrate can be established.

The above can be explained, for example, as follows. A phosphorus-containing copper alloy particle, a tin-containing particle and a nickel-containing particle react each other in a sintering process to form an electrode composed of a Cu—Sn—Ni alloy phase, a Sn—P—O glass phase and Cu—Sn alloy phase formed corresponding to a sintering condition. Since Cu—Sn—Ni alloy phase and the Cu—Sn alloy phase formed corresponding to a sintering condition are a compact bulk, the Sn—P—O glass phase is formed between the Cu—Sn—Ni alloy phase and the silicon substrate or between the Cu—Sn—Ni alloy phase and the Cu—Sn alloy phase and the silicon substrate, which is believed to improve the adhesion of the Cu—Sn alloy phase and the Cu—Sn—Ni alloy phase to the silicon substrate. Further, it is so conceivable that a good ohmic contact between an electrode formed by sintering and a silicon substrate can be established by the Sn—P—O glass phase functioning as a barrier layer prohibiting interdiffusion of copper and silicon. More particularly, it is conceivable that formation of a reaction phase (Cu₃Si) to be formed when an electrode containing copper is contacted directly with silicon and heated, can be suppressed to exhibit a good ohmic contact while maintaining adhesion to the silicon substrate and without deteriorating the semiconductor performance (for example, pn-junction property).

Namely, by combining a phosphorus-containing copper alloy particle with a tin-containing particle and a nickel-containing particle in the paste composition for an electrode, and firstly utilizing the reducing property of a phosphorus atom in a phosphorus-containing copper alloy particle with respect to an oxidized copper, an electrode having superior oxidation resistance and low volume resistivity is formed. Next by a reaction between the phosphorus-containing copper alloy particle and the tin-containing particle and the nickel-containing particle, while maintaining the volume resistivity low, a conductive layer composed of a Cu—Sn alloy phase, and an Sn—P—O glass phase are formed. And, for example, by the Sn—P—O glass phase functioning as a barrier layer preventing interdiffusion of copper and silicon, to suppress formation of a reactant phase between the electrode and the silicon substrate, a good ohmic contact with the copper electrode can be established. It is conceivable that the above two characteristic mechanisms can be exercised in a series of sintering processes.

Such an effect can be generally exerted if an electrode is formed on a substrate containing silicon with a paste composition for an electrode according to the present invention, and there is no particular restriction on a type of a substrate containing silicon. Examples of a substrate containing silicon include a silicon substrate for constituting a photovoltaic cell and a silicon substrate for producing a semiconductor device other than a photovoltaic cell.

(Phosphorous-Containing Copper Alloy Particles)

The paste composition for an electrode contains at least one phosphorus-containing copper alloy particle. As the phosphorous-containing copper alloy, a brazing material called copper phosphorus brazing (phosphorous concentration: approximately 7% by mass or less) is known. The copper phosphorus brazing is used as a copper to copper bonding agent, but by using the phosphorous-containing copper alloy particles as the copper-containing particles included in the paste composition for an electrode according to the present invention, the oxidation resistance is excellent and an electrode having a low volume resistivity can be formed. Furthermore, it becomes possible to sinter the electrode at a low temperature, and as a result, an effect of reducing a process cost can be attained.

In the present invention, the content of phosphorous included in the phosphorous-containing copper alloy particle is not limited. From the perspectives of oxidation resistance and low volume resistivity, the content of phosphorus is preferably from 6% by mass to 8% by mass, more preferably from 6.3% by mass to 7.8% by mass, and even more preferably from 6.5% by mass to 7.5% by mass. By setting the content of phosphorous included in the phosphorous-containing copper alloy to 8% by mass or less, a lower resistivity can be attained, and also, the productivity of the phosphorous-containing copper alloy is excellent. Further, by setting the content of phosphorous included in the phosphorous-containing copper alloy to 6% by mass or more, superior oxidation resistance can be attained.

The content of phosphorous included in the phosphorous-containing copper alloy can be measured by using a high frequency inductively-coupled plasma atomic emission spectrometer (ICP-AES).

The phosphorous-containing copper alloy particle is an alloy including copper and phosphorous and it may have other atoms. Examples of other atoms include Sb, Si, K, Na, Li, Ba, Sr, Ca, Mg, Be, Zn, Pb, Cd, Tl, V, Sn, Al, Zr, W, Mo, Ti, Co, Ni, and Au.

Furthermore, the content of other atoms included in the phosphorous-containing copper alloy particles can be set to, for example, 3% by mass or less in the phosphorous-containing copper alloy particles, and from the perspectives of the perspectives of the oxidation resistance and low volume resistivity, it is preferably 1% by mass or less.

The phosphorous-containing copper alloy particle may be used singly or in combination of two or more kinds thereof.

The average particle diameter of the phosphorous-containing copper alloy particle is not particularly limited, and it is preferably from 0.4 μm to 10 μm, and more preferably from 1 μm to 7 μm in terms of an average particle diameter when the cumulative weight is 50% (hereinafter abbreviated as “D50%” in some cases). By setting the particle diameter to 0.4 μm or more, the oxidation resistance is improved more effectively. Further, by setting the particle diameter to 10 μm or less, the contact area at where the phosphorous-containing copper alloy particles contact each other increases, whereby the resistivity is reduced more effectively.

In addition, the shape of the phosphorous-containing copper alloy particle is not particularly limited, and it may be any one of an approximately spherical shape, a flat shape, a block shape, a plate shape, a scale-like shape, and the like. From the perspectives of the oxidation resistance and the low volume resistivity, the shape of the phosphorous-containing copper alloy particle is preferably an approximately spherical shape, a flat shape, or a plate shape.

The content of the phosphorous-containing copper alloy particle in the paste composition for an electrode is not limited. From the perspective of low volume resistivity, the content of the phosphorous-containing copper alloy particle in the paste composition for an electrode is preferably from 15% by mass to 75% by mass, more preferably from 18% by mass to 70% by mass, and even more preferably from 20% by mass to 65% by mass.

The content of the phosphorous-containing copper alloy particle in the paste composition for an electrode can be measured by using a high frequency inductively-coupled plasma atomic emission spectrometer (ICP-AES) or a high frequency inductively-coupled plasma mass spectrometer (ICP-MS). When the content of the phosphorous-containing copper alloy particle is measured using these apparatus, the content of the phosphorous-containing copper alloy particle is measured by using a paste composition from which the solvent has been removed.

A phosphorous-containing copper alloy can be prepared by a generally used method. Further, the phosphorous-containing copper alloy particle can be prepared by a general method for preparing metal powders using a phosphorous-containing copper alloy that is prepared so as to give a desired phosphorous content, and it can be prepared by, for example, a general method using a water atomization method. The water atomization method is described in Handbook of Metal (MARUZEN CO., LTD. Publishing Dept.) or the like.

Specifically, for example, a desired phosphorous-containing copper alloy particle can be prepared by dissolving a phosphorous-containing copper alloy, forming a powder by nozzle spray, drying the obtained powders, and classifying them. Further, a phosphorous-containing copper alloy particle having a desired particle diameter can be prepared by appropriately selecting the classification condition.

(Tin-Containing Particle)

The paste composition for an electrode contains at least one tin-containing particle. By containing a tin-containing particle, an electrode having low volume resistivity can be formed in a sintering process described below.

There is no particular restriction on the tin-containing particle, insofar as it is a particle containing tin. Among others, it is preferably at least one selected from the group consisting of tin particles and tin alloy particles, and preferably at least one selected from the group consisting of tin particles and tin alloy particles having a tin content of 1% by mass or more.

There is no particular restriction on the purity of tin in a tin particle. For example the purity of a tin particle may be 95% by mass or more, is preferably 97% by mass or more, and more preferably 99% by mass or more.

There is no particular restriction on the kind of an alloy for a tin alloy particle, insofar as it is an alloy particle containing tin. Among others, from perspectives of the melting point of a tin alloy particle and the reactivity with a phosphorus-containing copper alloy particle and a nickel-containing copper alloy particle, a tin alloy particle with the tin content of 1% by mass or more is preferable, a tin alloy particle with the tin content of 3% by mass or more is more preferable, a tin alloy particle with the tin content of 5% by mass or more is further preferable, and a tin alloy particle with the tin content of 10% by mass or more is especially preferable.

The content of the tin in the tin-containing particle can be measured by using an X-ray fluorescence (XRF) spectrometer, for example, Type MESA-500W manufactured by HORIBA, Ltd.

Examples of a tin alloy particle include an Sn—Ag alloy, an Sn—Cu alloy, an Sn—Ag—Cu alloy, an Sn—Ag—Sb alloy, an Sn—Ag—Sb—Zn alloy, an Sn—Ag—Cu—Zn alloy, an Sn—Ag—Cu—Sb alloy, an Sn—Ag—Bi alloy, an Sn—Bi alloy, an Sn—Ag—Cu—Bi alloy, an Sn—Ag—In—Bi alloy, an Sn—Sb alloy, an Sn—Bi—Cu alloy, an Sn—Bi—Cu—Zn alloy, an Sn—Bi—Zn alloy, an Sn—Bi—Sb—Zn alloy, an Sn—Zn alloy, an Sn—In alloy, an Sn—Zn—In alloy, and an Sn—Pb alloy.

Among the tin alloy particles, specifically tin alloy particles of Sn-3.5Ag, Sn-0.7Cu, Sn-3.2Ag-0.5Cu, Sn-4Ag-0.5Cu, Sn-2.5Ag-0.8Cu-0.5Sb, Sn-2Ag-7.5Bi, Sn-3Ag-5Bi, Sn-58Bi, Sn-3.5Ag-3In-0.5Bi, Sn-3Bi-8Zn, Sn-9Zn, Sn-52In, Sn-40Pb or the like have the melting points same as Sn (232° C.) or even lower. Consequently the tin alloy particles can be used favorably, because they melt at an early stage of sintering to cover the surface of a phosphorus-containing copper alloy particle and can react homogeneously with the phosphorus-containing copper alloy particle. With respect to an expression of a tin alloy particle, for example, Sn-AX-BY-CZ means a tin alloy particle contains A % by mass of element X, B % by mass of element Y, and C % by mass of element Z.

According to the present invention the tin-containing particles may be used singly or used in a combination of 2 or more.

The tin-containing particle may further contain another atom which may unavoidably mix therein. Examples of an unavoidably mixing atom include Ag, Mn, Sb, Si, K, Na, Li, Ba, Sr, Ca, Mg, Be, Zn, Pb, Cd, Tl, V, Al, Zr, W, Mo, Ti, Co, Ni, and Au.

The content of another atom in the tin-containing particle may be for example 3% by mass or less of the tin-containing particle, and from perspectives of the melting point and the reactivity with a phosphorus-containing copper alloy particle it is preferably 1% by mass or less.

There is no particular restriction on the average particle diameter of the tin-containing particle and D50% of the tin-containing particles is preferably 0.5 μm to 20 μm, more preferably 1 μm to 15 μm, and further preferably 5 μm to 15 μm. When it is 0.5 μm or more, the oxidation resistance of a tin-containing particle itself can be improved. While, when it is 20 μm or less, the contact area in an electrode with a phosphorus-containing copper alloy particle and a nickel-containing particle can be increased to promote effectively a reaction during sintering.

Further, there is no particular restriction on the shape of the tin-containing particle, and it may be any of approximately spherical, flat, blocky, platy, scaly or the like. From the perspectives of oxidation resistance and low volume resistivity, it is preferably approximately spherical, flat, or platy.

Further, there is no particular restriction on the content of a tin-containing particle in a paste composition for an electrode according to the present invention. Among others, when the total content of the phosphorus-containing copper alloy particle and the tin-containing particle and the nickel-containing particle is 100% by mass, the content of a tin-containing particle is preferably from 5% by mass to 70% by mass, more preferably from 7% by mass to 65% by mass, further preferably from 9% by mass to 60% by mass and particularly preferably from 9% by mass to 45% by mass.

When the content of a tin-containing particle is 5% by mass or more, the reaction with a phosphorus-containing copper alloy particle and a nickel-containing particle can be progressed more homogeneously. Further, when a tin-containing particle is set at 70% by mass or less, a sufficient volume of Cu—Sn alloy phase and Cu—Sn—Ni alloy phase can be formed to lower the volume resistivity of an electrode.

The content of the tin-containing particle in the paste composition for an electrode can be measured by using a high frequency inductively-coupled plasma atomic emission spectrometer (ICP-AES) or a high frequency inductively-coupled plasma mass spectrometer (ICP-MS). When the content of the tin-containing particle is measured using these apparatus, the content of the tin-containing particle is measured by using a paste composition from which the solvent has been removed.

(Nickel-Containing Particle)

The paste composition for an electrode according to the present invention contains at least one nickel-containing particle. By containing a nickel-containing particle in addition to a phosphorus-containing copper alloy particle and a nickel-containing particle, oxidation resistance can be exhibited at higher temperature in a sintering process.

There is no particular restriction on the nickel-containing particle, insofar as it is a particle containing nickel. Among others, it is preferably at least one selected from the group consisting of nickel particles and nickel alloy particles, and preferably at least one selected from the group consisting of nickel particles and nickel alloy particles having a nickel content of 1% by mass or more.

There is no particular restriction on the purity of nickel in a nickel particle. For example the purity of a nickel particle may be 95% by mass or more, is preferably 97% by mass or more, and more preferably 99% by mass or more.

There is no restriction on the kind of an alloy for a nickel alloy particle, insofar as it is an alloy particle containing nickel. Among others, from perspectives of the melting point of a nickel alloy particle and the reactivity with a phosphorus-containing copper alloy particle, a tin-containing copper alloy particle and a Cu—Sn alloy phase, a nickel alloy particle with the nickel content of 1% by mass or more is preferable, a nickel alloy particle with the nickel content of 3% by mass or more is more preferable, a nickel alloy particle with the nickel content of 5% by mass or more is further preferable, and a nickel alloy particle with the nickel content of 10% by mass or more is especially preferable.

The content of the nickel in the nickel-containing particle can be measured by using an X-ray fluorescence (XRF) spectrometer, for example, Type MESA-500W manufactured by HORIBA, Ltd.

Examples of a nickel alloy particle include a Ni—Fe alloy, a Ni—Cu alloy, a Ni—Cu—Zn alloy, a Ni—Cr alloy, a Ni—Cr—Ag alloy. In particular, the nickel alloy particles such as Ni-58Fe, Ni-75Cu, Ni-6Cu-20Zn can be used favorably, because they can react homogeneously with the phosphorus-containing copper alloy particle and tin-containing particle. With respect to an expression of a nickel alloy particle, for example, Ni-AX-BY-CZ means a nickel alloy particle contains A % by mass of element X, B % by mass of element Y, and C % by mass of element Z.

According to the present invention the nickel-containing particles may be used singly or used in a combination of 2 or more.

The nickel-containing particle may further contain another atom which may unavoidably mix therein. Examples of an unavoidably mixing atom include Ag, Mn, Sb, Si, K, Na, Li, Ba, Sr, Ca, Mg, Be, Zn, Pb, Cd, Tl, V, Al, Zr, W, Mo, Ti, Co, Sn, and Au.

The content of another atom in the nickel-containing particle may be for example 3% by mass or less of the nickel-containing particle, and from perspectives of the melting point and the reactivity with a phosphorus-containing copper alloy particle and tin-containing particle it is preferably 1% by mass or less.

There is no particular restriction on the average particle diameter of the nickel-containing particle and D50% of the nickel-containing particles is preferably 0.5 μm to 20 μm, more preferably 1 μm to 15 μm, and further preferably 5 μm to 15 μm. When it is 0.5 μm or more, the oxidation resistance of a nickel-containing particle itself can be improved. While, when it is 20 μm or less, the contact area in an electrode with a phosphorus-containing copper alloy particle and a tin-containing particle can be increased to promote more effectively a reaction with the phosphorus-containing copper alloy particle and the tin-containing particle.

There is no particular restriction on the shape of the nickel-containing particle, and it may be any of approximately spherical, flat, blocky, platy, scaly, etc. From the perspectives of oxidation resistance and low volume resistivity, it is preferably approximately spherical, flat, or platy.

Further, there is no particular restriction on the content of a nickel-containing particle in a paste composition for an electrode according to the present invention. Among others, when the total content of the phosphorus-containing copper alloy particle, the tin-containing particle, and the nickel-containing particle is 100% by mass, the content of a nickel-containing particle is preferably from 10% by mass to 60% by mass, more preferably from 12% by mass to 55% by mass, further preferably from 15% by mass to 50% by mass and particularly preferably from 15% by mass to 35% by mass.

When the content of a nickel-containing particle is 10% by mass or more, the formation of Cu—Sn—Ni alloy phase can be progressed more homogeneously. Further, when a nickel-containing particle is set at 70% by mass or less, a sufficient volume of Cu—Sn—Ni alloy phase can be formed to lower volume resistivity of an electrode.

The content of the nickel-containing particle in the paste composition for an electrode can be measured by using a high frequency inductively-coupled plasma atomic emission spectrometer (ICP-AES) or a high frequency inductively-coupled plasma mass spectrometer (ICP-MS). When the content of the nickel-containing particle is measured using these apparatus, the content of the nickel-containing particle is measured by using a paste composition from which the solvent has been removed.

There is no particular restriction on the content ratio of the tin-containing particle and the nickel-containing particle in the paste composition for an electrode. From the perspective of adhesiveness to the silicon substrate, the mass ratio of the nickel-containing particle to the tin-containing particle (nickel-containing particle/tin-containing particle) is preferably 0.3 to 4.0 and more preferably 0.4 to 3.0.

In addition, there is no particular restriction on the content ratio of the phosphate-containing copper alloy particle, and the tin-containing particle and the nickel-containing particle in the paste composition for an electrode. From the perspective of the low volume resistivity of an electrode to be formed in a sintering condition at high temperature and from the perspective of adhesiveness to the silicon substrate, the mass ratio of the total amount of the tin particle-containing particle and the nickel-containing particle to the phosphate-containing copper alloy particle ((nickel-containing particle+tin-containing particle)/phosphate-containing copper alloy particle) is preferably 0.4 to 1.8, and more preferably 0.6 to 1.4.

Further, there is no particular restriction on the ratio of the average particle diameter (D50%) of the tin-containing particle and the average particle diameter (D50%) of the nickel-containing particle in the paste composition for an electrode. From the perspectives of the homogeneity of the Sn—P—O glass phase to be formed and from the perspective of adhesiveness to the silicon substrate, the ratio of the average particle diameter (D50%) of the nickel-containing particle to the average particle diameter (D50%) of the tin particle-containing particle (nickel-containing particle/tin-containing particle) is preferably 0.05 to 20, and more preferably 0.5 to 10.

In addition, there is no particular restriction on the ratio of the average particle diameter (D50%) of the phosphate-containing copper alloy and the average particle diameter (D50%) of the tin-containing particle in the paste composition for an electrode. From the perspective of the low volume resistivity of an electrode to be formed in a sintering condition at high temperature and from the perspective of adhesiveness to the silicon substrate, the ratio of the average particle diameter (D50%) of the tin-containing particle to the average particle diameter (D50%) of the phosphate-containing copper alloy particle (tin-containing particle/phosphate-containing copper alloy) is preferably 0.03 to 30, and more preferably 0.1 to 10.

In addition, there is no particular restriction on the ratio of the average particle diameter (D50%) of the phosphate-containing copper alloy and the average particle diameter (D50%) of the nickel-containing particle in the paste composition for an electrode. From the perspective of the low volume resistivity of an electrode to be formed in a sintering condition at high temperature, the ratio of the average particle diameter (D50%) of the nickel-containing particle to the average particle diameter (D50%) of the phosphate-containing copper alloy particle (nickel-containing particle/phosphate-containing copper alloy) is preferably 0.02 to 20, and more preferably 0.1 to 10.

(Glass Particles)

The paste composition for an electrode according to the present invention includes at least one kind of glass particles. By incorporating glass particles in the paste composition for an electrode, a silicon nitride film which is an anti-reflection film is removed by a so-called fire-through at an electrode-forming temperature, and an ohmic contact between the electrode and the silicon substrate is formed.

From the perspectives of adhesiveness to a silicon substrate and low volume resistivity of the electrode, a glass particle containing glass having a glass softening point of 650° C. or lower and a crystallization starting temperature of higher than 650° C. is preferred. Further, the glass softening point is measured by a conventional method using a Thermo Mechanical Analyzer (TMA), for example Type TMA-60 manufactured by SHIMADZU CORPORATION, and the crystallization starting temperature is measured by a conventional method using a Thermo Gravimetry/Differential Thermal Analyzer (TG/DTA), for example Type DTG-60H manufactured by SHIMADZU CORPORATION.

Specifically, in, for example, a thermal expansion curve measured by the TMA, an intersection point is obtained between two tangent lines from two different tangent points. A temperature corresponding to the intersection point is identified as the glass softening point. Further, an exothermic peak is identified from an analysis curve of the TG-DTA, and an intersection point is obtained between a tangent line from a tangent point before the exothermic region of the analysis curve and a tangent line from a tangent point between starting point of exothermic region and the exothermic peak of the analysis curve. A temperature corresponding to the intersection point is identified as the crystallization starting temperature.

When the paste composition for an electrode is used as an electrode of light receiving surface side, any known glass particles in the related art may be used without any particular limitation, provided the glass particles softened or melted at an electrode-forming temperature to contact with the silicon nitride, thereby oxidizing the silicon nitride and incorporating the oxidized silicon dioxide thereof to remove antireflective film.

The glass particles generally included in the paste composition for an electrode may be constituted with lead-containing glass, at which silicon dioxide can be efficiently incorporated. Examples of such lead-containing glass include those described in Japanese Patent No. 03050064 and the like, which can be suitably used in the present invention.

Furthermore, in the present invention, in consideration of the effect on the environment, it is preferable to use lead-free glass which does not substantially contain lead. Examples of the lead-free glass include lead-free glass described in Paragraphs 0024 to 0025 of JP-A No. 2006-313744, and lead-free glass described in JP-A No. 2009-188281 and the like, and it is also preferable to appropriately select one from the lead-free glass as above and apply it in the present invention.

When the paste composition for an electrode is used as, for example, an rear surface extraction electrode, a through hole electrode in a back-contact type photovoltaic cell element, and a rear surface electrode except for an electrode of light receiving surface of a photovoltaic cell, a glass particle which does not contain an ingredient required for fire-through such as lead can be used.

Examples of the glass component constituting the glass particles used in the paste composition for an electrode include silicon dioxide (SiO₂), phosphorous oxide (P₂O₅), aluminum oxide (Al₂O₃), boron oxide (B₂O₃), vanadium oxide (V₂O₅), potassium oxide (K₂O), bismuth oxide (Bi₂O₃), sodium oxide (Na₂O), lithium oxide (Li₂O), barium oxide (BaO), strontium oxide (SrO), calcium oxide (CaO), magnesium oxide (MgO), beryllium oxide (BeO), zinc oxide (ZnO), lead oxide (PbO), cadmium oxide (CdO), tin oxide (SnO), zirconium oxide (ZrO₂), tungsten oxide (WO₃), molybdenum oxide (MoO₃), lanthanum oxide (La₂O₃), niobium oxide (Nb₂O₅), tantalum oxide (Ta₂O₅), yttrium oxide (Y₂O₃), titanium oxide (TiO₂), germanium oxide (GeO₂), tellurium oxide (TeO₂), lutetium oxide (Lu₂O₃), antimony oxide (Sb₂O₃), copper oxide (CuO), iron oxide (FeO), silver oxide (Ag₂O), and manganese oxide (MnO).

Among these, a glass particle containing at least one glass component selected from the group consisting of SiO₂, P₂O₅, Al₂O₃, B₂O₃, V₂O₅, Bi₂O₃, ZnO, and PbO is preferably used, and a glass particle containing at least one glass component selected from the group consisting of SiO₂, PbO, B₂O₃, Bi₂O₃, and Al₂O₃ is more preferably used. With such a glass particle, the softening point can be lowered more effectively. Further, since the wettability with a phosphorus-containing copper alloy particle, a tin-containing particle, a nickel-containing particle, and a silver particle which may be contained as necessary, is improved, sintering among the particles in the sintering process proceeds well and an electrode having lower volume resistivity can be formed.

Meanwhile, from the perspective of low contact resistivity, a glass particle containing phosphorus pentoxide (phosphate glass, P₂O₅ based glass particle) is preferable, and a glass particle containing vanadium pentoxide in addition to phosphorus pentoxide (P₂O₅—V₂O₅ based glass particle) is more preferable. By containing additionally vanadium pentoxide, the oxidation resistance improves further, and the resistivity of an electrode decreases further. The above is apparently attributable to decrease in the glass softening point by containing additionally, for example, vanadium pentoxide. If a phosphorus pentoxide-vanadium pentoxide glass particle (P₂O₅—V₂O₅ glass particle) is used, the content of vanadium pentoxide based on the total mass of the glass is preferably 1% by mass or more, and more preferably 1% by mass to 70% by mass.

There is no particular restriction on the average particle diameter of a glass particle according to the present invention, and the average particle diameter at an accumulated weight of 50% (D50%) is preferably from 0.5 μm to 10 μm, and more preferably from 0.8 μm to 8 μm. When it is 0.5 μm or more the workability in producing a paste composition for an electrode is improved. Further, when it is 10 μm or less, the particle can be dispersed homogeneously in a paste composition for an electrode, and fire-through can efficiently take place in a sintering process, and further the adhesiveness to a silicon substrate is improved.

Further, there is no particular restriction on the shape of the glass particle, and it may be any of approximately spherical, flat, blocky, platy, scaly, etc. From the perspective of oxidation resistance and low volume resistivity, it is preferably approximately spherical, flat, or platy.

The content of the glass particle based on the total mass of a paste composition for an electrode is preferably 0.1% by mass to 10% by mass, more preferably 0.5% by mass to 8% by mass, and further preferably 1% by mass to 8% by mass. When the glass particle is contained in the content range, oxidation resistance, lower electrode volume resistivity, and lower contact resistivity can be attained more effectively, and the reaction between the phosphorus-containing copper alloy particle and, the tin-containing particle and nickel-containing particle can be promoted.

The content of the glass particle in the paste composition for an electrode can be measured by using a high frequency inductively-coupled plasma atomic emission spectrometer (ICP-AES) or a high frequency inductively-coupled plasma mass spectrometer (ICP-MS). When the content of the glass particle is measured using these apparatus, the content of the glass particle is measured by using a paste composition from which the solvent has been removed.

The ratio of the content of the glass particle to the total content of a phosphorus-containing copper alloy particle, a tin-containing particle, a nickel-containing particle and a silver particle, which may be contained as needed in a paste composition for an electrode is preferably from 0.01 to 0.15%, more preferably 0.03 to 0.12. When the glass particle is contained in such content range, oxidation resistance, lower electrode volume resistivity, and lower contact resistivity can be attained more effectively, and the reaction between the phosphorus-containing copper alloy particle and, the tin-containing particle and nickel-containing particle can be promoted.

Further, the ratio of the average particle diameter (D50%) of the glass particle to the average particle diameter (D50%) of a phosphorus-containing copper alloy particle in a paste composition for an electrode is preferably from 0.05 to 100, more preferably 0.1 to 20. If the glass particle is contained in such range, oxidation resistance, lower electrode volume resistivity, and lower contact resistivity can be attained more effectively, and the reaction between the phosphorus-containing copper alloy particle and, the tin-containing particle and nickel-containing particle can be promoted.

(Solvent and Resin)

The paste composition for an electrode according to the present invention includes at least one kind of solvent and at least one kind of resin, thereby enabling adjustment of the liquid physical properties (for example, viscosity and surface tension) of the paste composition for an electrode according to the present invention due to application method, when selected the paste composition is provided to a silicon substrate.

The solvent is not particularly limited. Examples of the solvent include hydrocarbon-based solvents such as hexane, cyclohexane, and toluene; chlorinated hydrocarbon-based solvents such as dichloroethylene, dichloroethane, and dichlorobenzene; cyclic ether-based solvents such as tetrahydrofuran, furan, tetrahydropyran, pyran, dioxane, 1,3-dioxolane, and trioxane; amide-based solvents such as N,N-dimethylformamide and N,N-dimethylacetamide; sulfoxide-based solvents such as dimethylsulfoxide, diethylsulfoxide; ketone-based solvents such as acetone, methyl ethyl ketone, diethyl ketone, and cyclohexanone; alcohol-based compounds such as ethanol, 2-propanol, 1-butanol, and diacetone alcohol; polyhydric alcohol ester-based solvents such as 2,2,4-trimethyl-1,3-pentanediol monoacetate, 2,2,4-trimethyl-1,3-pentanediol monopropionate, 2,2,4-trimethyl-1,3-pentanediol monobutyrate, 2,2,4-trimethyl-1,3-pentanediol monoisobutyrate, 2,2,4-triethyl-1,3-pentanediol monoacetate, ethylene glycol monobutyl ether acetate, and diethylene glycol monobutyl ether acetate; polyhydric alcohol ether-based solvents such as butyl cellosolve and diethylene glycol diethyl ether; terpene-based solvents such as terpineol which includes α-terpineol, terpinene which includes α-terpinene, pinene which includes α-pinene and β-pinene, myrcene, alloocimene, limonene, dipentene, carvone, ocimene, and phellandrene, and mixtures thereof.

As the solvent in the present invention, from the perspectives of applicability and printability when forming the paste composition for an electrode on a silicon substrate, at least one selected from the group consisting of polyhydric alcohol ester-based solvents, terpene-based solvents, and polyhydric alcohol ether-based solvents is preferred, and at least one selected from the group consisting of polyhydric alcohol ester-based solvents and terpene-based solvents is more preferred. In the present invention, the solvents may be used singly or in combination of two or more kinds thereof.

Furthermore, as the resin, a resin that is generally used in the art can be used without any limitation as long as it is a resin that is thermally decomposable by sintering. Specific examples of the resin include cellulose-based resins such as methyl cellulose, ethyl cellulose, carboxymethyl cellulose, and nitrocellulose; polyvinyl alcohols; polyvinyl pyrrolidones; acryl resins; vinyl acetate-acrylic ester copolymers; butyral resins such as polyvinyl butyral; alkyd resins such as phenol-modified alkyd resins and castor oil fatty acid-modified alkyd resins; epoxy resins; phenol resins; and rosin ester resins.

As the resin in the present invention, from the perspective of the loss at a time of sintering, at least one selected from the group consisting of cellulose-based resins and acryl resins is preferred, and at least one selected from cellulose-based resins is more preferred. In the present invention, the resins may be used singly or in combination of two or more kinds thereof.

There is no particular restriction on the weight-average molecular weight of the resin according to the present invention. Among others, the weight-average molecular weight is preferably from 5,000 or more to 500,000 or less, and more preferably from 10,000 or more to 300,000 or less. When the weight-average molecular weight of the resin is 5,000 or more, increase in the viscosity of a paste composition for an electrode can be suppressed. This is apparently attributable to, for example, mutual aggregation of particles due to insufficient steric repulsion when the resin is adsorbed on a phosphorus-containing copper alloy particle, a tin-containing particle, and a nickel-containing particle. Meanwhile, when the weight-average molecular weight of the resin is 500,000 or less, mutual aggregation of the resins in a solvent is suppressed and increase in the viscosity of a paste composition for an electrode can be suppressed.

Additionally, when the weight-average molecular weight of the resin is 500,000 or less, increase in the combustion temperature of the resin can be suppressed, and when a paste composition for an electrode is subjected to sintering, appearance of a residual foreign material due to incomplete combustion of the resin can be suppressed, to form an electrode having lower volume resistivity.

The contents of the solvent and the resin in a paste composition for an electrode according to the present invention can be selected appropriately depending on a desired liquid property and the kinds of the solvent and the resin to be used. For example, the total content of the solvent and the resin is preferably from 3% by mass to 29.9% by mass based on the total mass of a paste composition for an electrode, more preferably from 5% by mass to 25% by mass, and further preferably from 7% by mass to 20% by mass.

When the total content of the solvent and the resin is within the range, the application property in applying a paste composition for an electrode to a silicon substrate becomes favorable, and an electrode having a desired width and height can be formed easier.

Further, with respect to a paste composition for an electrode according to the present invention, from the perspectives of oxidation resistance and low volume resistivity of an electrode, preferably the total content of a phosphorus-containing copper alloy particle, a tin-containing particle, and a nickel-containing particle is from 70% by mass to 94% by mass, the content of a glass particle is from 0.1% by mass to 10% by mass, and the total content of a solvent and a resin is from 3% by mass to 29.9% by mass; more preferably the total content of a phosphorus-containing copper alloy particle, a tin-containing particle, and a nickel-containing particle is from 74% by mass to 88% by mass, the content of a glass particle is from 0.5% by mass to 8% by mass, and the total content of a solvent and a resin is from 7% by mass to 20% by mass; and further preferably the total content of a phosphorus-containing copper alloy particle, a tin-containing particle, and a nickel-containing particle is from 74% by mass to 88% by mass, the content of a glass particle is from 1% by mass to 8% by mass, and the total content of a solvent and a resin is from 7% by mass to 20% by mass.

(Silver Particle)

A paste composition for an electrode according to the present invention should preferably include further a silver particle. By incorporating of a silver particle, the oxidation resistance increases and volume resistivity of an electrode to be formed decreases. Further by separation of an Ag particle in a Sn—P—O glass phase generated by a reaction between the phosphorus-containing copper alloy particle and the tin-containing particle, the ohmic contact between a Cu—Sn—Ni alloy phase and Cu—Sn alloy phase in an electrode layer and a silicon substrate improves further. Additionally, when assembled to a photovoltaic cell module, an effect of improving the solder wetting property can be obtained.

Silver constituting the silver particle may further contain other atoms which are inevitably incorporated. Examples of other atoms which are inevitably incorporated include Sb, Si, K, Na, Li, Ba, Sr, Ca, Mg, Be, Zn, Pb, Cd, Tl, V, Sn, Al, Zr, W, Mo, Ti, Co, Ni, and Au.

The content of other atoms in the silver particle may be for example 3% by mass or less of the silver particle, and from the perspectives of the melting point and decrease in electrode volume resistivity it is preferably 1% by mass or less.

There is no particular restriction on the average particle diameter of a silver particle according to the present invention, and the average particle diameter at an accumulated weight of 50% (D50%) is preferably from 0.4 μm to 10 μm, and more preferably from 1 μm to 7 μm. If it is 0.4 μm or more the oxidation resistance is improved more effectively. Further if it is 10 μm or less, the contact area between a silver particle and a phosphorus-containing copper alloy particle, tin-containing particle and nickel-containing particle in an electrode can be larger, and the resistivity decreases more effectively.

Further, there is no particular restriction on the shape of the silver particle, and it may be any of approximately spherical, flat, blocky, platy, scaly, etc. From the perspectives of oxidation resistance and low volume resistivity, however, it is preferably approximately spherical, flat, or platy.

Further, in cases where the paste composition for an electrode contains a silver particle, the content of a silver particle is preferably from 0.1% by mass to 10% by mass based on the total content of the phosphorus-containing copper alloy particle, the tin-containing particle, the nickel-containing particle, and the silver particle as 100% by mass, and more preferably from 0.5% by mass to 8% by mass.

The content of the silver particle can be measured by using an X-ray fluorescence (XRF) spectrometer, for example, Type MESA-500W manufactured by HORIBA, Ltd.

With respect to a paste composition for an electrode according to the present invention, from the perspectives of oxidation resistance, low volume resistivity of an electrode, and applicability to a silicon substrate, the total content of a phosphorus-containing copper alloy particle, a tin-containing particle, a nickel-containing particle and a silver particle in a paste composition for an electrode is preferably from 70% by mass to 94% by mass, and more preferably from 74% by mass to 88% by mass. When the total content of a phosphorus-containing copper alloy particle, a tin-containing particle, a nickel-containing particle, and a silver particle is 70% by mass or more a favorable viscosity for applying a paste composition for an electrode can be obtained easily. While, when the total content of a phosphorus-containing copper alloy particle, a tin-containing particle, a nickel-containing particle, and a silver particle is 94% by mass or less, appearance of a scarcely coated spot in applying a paste composition for an electrode can be more effectively suppressed.

When a paste composition for an electrode according to the present invention contains a silver particle additionally, from the perspectives of oxidation resistance and low volume resistivity of an electrode, preferably the total content of a phosphorus-containing copper alloy particle, a tin-containing particle, a nickel-containing particle, and a silver particle is from 70% by mass to 94% by mass, the content of a glass particle is from 0.1% by mass to 10% by mass, and the total content of a solvent and a resin is from 3% by mass to 29.9% by mass; more preferably the total content of a phosphorus-containing copper alloy particle, a tin-containing particle, a nickel-containing particle, and a silver particle is from 74% by mass to 88% by mass, the content of a glass particle is from 0.5% by mass to 8% by mass, and the total content of a solvent and a resin is from 7% by mass to 20% by mass; and further preferably the total content of a phosphorus-containing copper alloy particle, a tin-containing particle, a nickel-containing particle, and a silver particle is from 74% by mass to 88% by mass, the content of a glass particle is from 1% by mass to 8% by mass, and the total content of a solvent and a resin is from 7% by mass to 20% by mass.

(Flux)

The paste composition for an electrode may include at least one flux additionally. By incorporating of a flux, an oxidized film formed on a surface of a phosphorus-containing copper alloy particle can be removed and a reducing reaction of a phosphorus-containing copper alloy particle during sintering can be promoted. Further, melting of a tin-containing particle during sintering is also promoted to promote a reaction with a phosphorus-containing copper alloy particle, resulting in improvement of the oxidation resistance to lower the volume resistivity of a formed electrode. Additionally, an effect of enhancing the adhesion between an electrode material and a silicon substrate can be obtained.

The flux in the present invention is not particularly limited as long as it can remove an oxide film formed on the surface of the copper-containing particle. Specific preferable examples of the flux include fatty acids, boric acid compounds, fluoride compounds, and fluoroborate compounds.

More specific examples thereof include lauric acid, myristic acid, palmitic acid, stearic acid, sorbic acid, stearol acid, propionic acid, boron oxide, potassium borate, sodium borate, lithium borate, potassium fluoroborate, sodium fluoroborate, lithium fluoroborate, acidic potassium fluoride, acidic sodium fluoride, acidic lithium fluoride, potassium fluoride, sodium fluoride, and lithium fluoride.

Among those, from the perspective of heat resistance at a time of sintering the electrode material (a property that the flux is not volatilized at a low sintering temperature) and complementing the oxidation resistance of the phosphorous-containing copper alloy particle, particularly preferable examples of the flux include potassium borate and potassium fluoroborate.

In the present invention, these fluxes can be respectively used singly or in combination of two or more kinds thereof.

When the paste composition for an electrode includes a flux, the content of the flux in the paste composition for an electrode is preferably from 0.1% by mass to 5% by mass, more preferably from 0.3% by mass to 4% by mass, even more preferably from 0.5% by mass to 3.5% by mass, particularly preferably from 0.7% by mass to 3% by mass, and extremely preferably from 1% by mass to 2.5% by mass, based on the total mass of the paste composition for an electrode, from the perspective of effectively exhibiting the oxidation resistance of the phosphorous-containing copper alloy particles and from the perspective of reducing the porosity of a portion from which the flux is removed at a time of completion of the sintering of the electrode material.

(Other Components)

Furthermore, the paste composition for an electrode according to the present invention can include, in addition to the above-described components, other components generally used in the art, if necessary. Examples of other components include a plasticizer, a dispersant, a surfactant, an inorganic binder, a metal oxide, a ceramic, and an organic metal compound.

The method for preparing the paste composition for an electrode according to the present invention is not particularly limited. The paste composition for an electrode according to the present invention can be prepared by dispersing and mixing phosphorous-containing copper alloy particles, tin-containing particles, nickel-containing particles, the glass particles, a solvent, a resin, and silver particles to be added, if necessary, and the like, using a method that is generally used for dispersing or mixing. A method for dispersing or mixing is not particularly limited, and the method may be selected appropriately from methods that are generally used for dispersing or mixing.

<Method for Producing Electrode Using Paste Composition for Electrode>

As for the method for preparing an electrode using the paste composition for an electrode according to the present invention, the paste composition for an electrode can be provided in a region in which the electrode is formed, dried, and then sintered to form the electrode in a desired region. By using the paste composition for an electrode, an electrode having low volume resistivity can be formed even with a sintering treatment in the presence of oxygen (for example, in the atmosphere).

Specifically, for example, when an electrode for a photovoltaic cell is formed using the paste composition for an electrode, the paste composition for an electrode can be provided to a silicon substrate to a desired shape, dried, and then sintered to form an electrode for a photovoltaic cell having a low resistivity in a desired shape. Further, by using the paste composition for an electrode, an electrode having a low resistivity can be formed even with a sintering treatment in the presence of oxygen (for example, in the atmosphere).

Examples of the method for providing the paste composition for an electrode on a silicon substrate include screen printing, an ink-jet method, and a dispenser method, but from the perspective of the productivity, application by screen printing is preferred.

When the paste composition for an electrode according to the present invention is applied by screen printing, it is preferable that the viscosity be in the range from 20 Pa·s to 1000 Pa·s. Further, the viscosity of the paste composition for an electrode is measured using a Brookfield HBT viscometer at 25° C.

The amount of the paste composition for an electrode to be provided can be appropriately selected according to the size of the electrode formed. For example, the amount of the paste composition for an electrode to be provided can be from 2 g/m² to 10 g/m², and preferably from 4 g/m² to 8 g/m².

Moreover, as a heat treatment condition (sintering condition) when forming an electrode using the paste composition for an electrode according to the present invention, heat treatment conditions generally used in the art can be applied. Generally, the heat treatment temperature (sintering temperature) is from 800° C. to 900° C., but when using the paste composition for an electrode according to the present invention, a heat treatment condition can be applied in a wide range from a lower temperature heat treatment condition to a generally used heat treatment condition, and for example, an electrode having excellent characteristics can be formed at a wide range of heat treatment temperature of from 450° C. to 900° C.

In addition, the heat treatment time can be appropriately selected according to the heat treatment temperature and the like, and it may be, for example, 1 second to 20 seconds.

As a heat treatment equipment, one able to elevate the above described temperature may be adopted appropriately, and examples include an infrared heating oven, and a tunnel oven. By an infrared heating oven, electrical energy is input directly to a heated material in a form of an electromagnetic wave and converted to thermal energy, and therefore the efficiency is high, and rapid heating in a short time period is possible. Further, since there is no combustion product, and it is noncontact heating, contamination of a produced electrode can be prevented. By a tunnel oven, since a sample is conveyed automatically and continuously from an inlet to an outlet to undergo sintering, homogeneous sintering is possible by segmentation of the oven and control of the conveying speed. From the perspective of the electricity generation performance of a photovoltaic cell element, heat treatment by a tunnel oven is favorable.

<Photovoltaic Cell and Method for Producing the Same>

A photovoltaic cell element according to the present invention at least includes a silicon substrate having a pn-junction and an electrode which is sintered material of the paste composition for an electrode applied on to the silicon substrate. As the result, a photovoltaic cell element having favorable characteristics can be obtained, and the productivity of the photovoltaic cell element is superior.

Meanwhile, the term “photovoltaic cell element” means herein an element having a silicon substrate having a pn-junction and an electrode formed on the silicon substrate. Further, the term “photovoltaic cell” means an assembly constituted, according to need, by connecting by means of a wiring material plural photovoltaic cell elements, whose electrodes are provided with the wiring material, and encapsulated by an encapsulation resin.

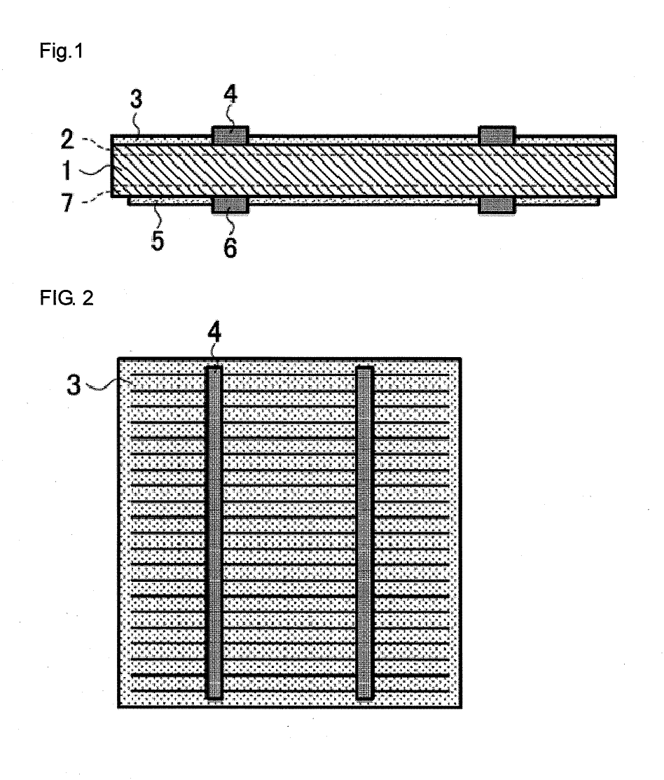

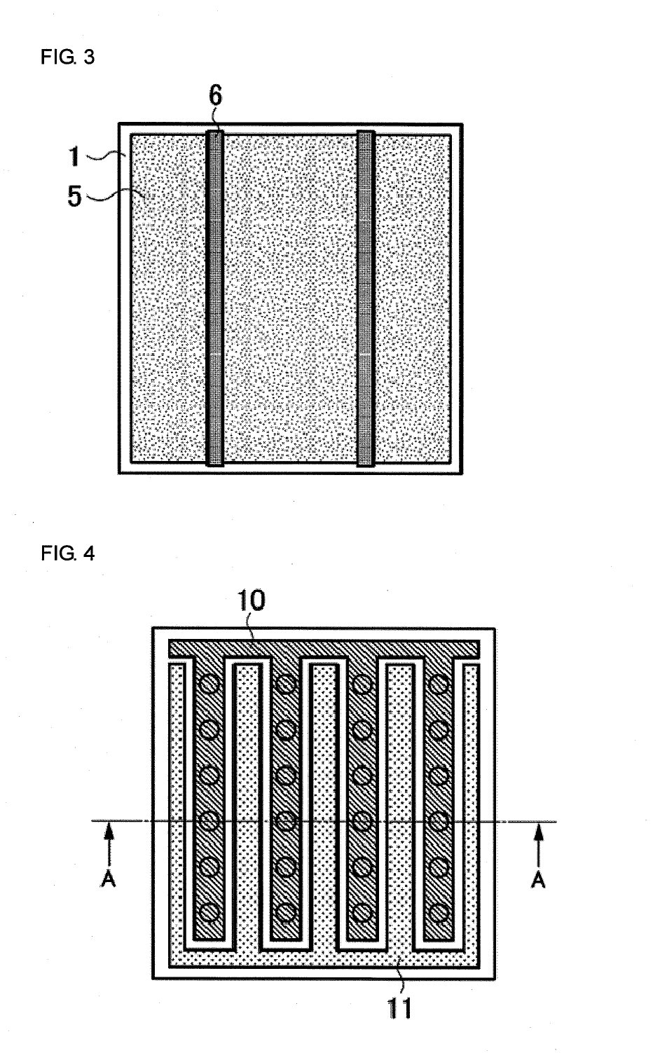

Specific examples of a photovoltaic cell element according to the present invention will be described below with reference to the drawings, provided that the present invention be not limited thereto. FIG. 1, FIG. 2, and FIG. 3 show a cross-sectional view, schematic views of a light receiving surface and a back surface of an example of a typical photovoltaic cell element.

As illustrated in a schematic cross-sectional view in FIG. 1, in the vicinity of the surface of one side of the semiconductor substrate 1 an n⁺ diffusion layer 2 is formed, and on the n⁺ diffusion layer 2 a power output electrode 4 and an antireflection coating 3 are formed. In the vicinity of the surface of the other side of the semiconductor substrate a p⁺ diffusion layer 7 is formed, and on the p⁺ diffusion layer 7 a back surface power output electrode 6 and a back surface collecting electrode 5 are formed. As a semiconductor substrate 1 of a photovoltaic cell element is usually utilized a monocrystalline or polycrystalline silicon, or the like. The semiconductor substrate 1 contains boron or the like constituting a p-type semiconductor. On the light receiving surface side asperity (also called as “texture”, not illustrated) is formed by an etching solution composed of NaOH and IPA (isopropyl alcohol) to suppress reflection. On this light receiving surface side phosphorus or the like is doped to provide an n⁺ diffusion layer 2 with the thickness of a sub-micron scale, and at a boundary with a p-type bulk a pn-junction region is formed. Further on the light receiving surface side, an antireflection coating 3 made of silicon nitride, etc. is provided on the n⁺ diffusion layer 2 with the film thickness of approx. 90 nm by means of PECVD, etc.

Next, a method for forming a light receiving surface electrode 4 provided on the light receiving surface side as outlined in FIG. 2, and a collecting electrode 5 and a power output electrode 6 to be formed on the back surface as outlined in FIG. 3 will be described.

A light receiving surface electrode 4 and a back surface power output electrode 6 are formed with the paste composition for an electrode. While, a back surface collecting electrode 5 is formed with an aluminum electrode paste composition containing a glass powder. As the first example of methods for forming a light receiving surface electrode 4, a back surface collecting electrode 5, and a back surface power output electrode 6, the paste compositions are coated by screen printing, etc. in desired patterns, dried and sintered simultaneously in the atmosphere at approx. 450° C. to 900° C. to complete the electrodes. According to the present invention by using the paste composition for an electrode, an electrode superior in resistivity and contact resistivity can be formed even by sintering at a relatively low temperature.

On that occasion, on the light receiving surface side, a glass particle contained in the paste composition for an electrode forming a light receiving surface electrode 4 reacts with an antireflection layer 3 (fire-through) to establish an electrical connection (ohmic contact) between the light receiving surface electrode 4 and an n⁺ diffusion layer 2.

According to the present invention, by forming a light receiving surface electrode 4 with the paste composition for an electrode, containing copper as a conductive metal, oxidization of the copper can be suppressed and a light receiving surface electrode 4 with low resistivity can be formed at a high productivity.

Further, according to the present invention, a formed electrode should preferably be constituted by including a Cu—Sn—Ni alloy phase and a Cu—Sn alloy phase as needed, and an Sn—P—O glass phase, and more preferably by placing the Sn—P—O glass phase between the Cu—Sn alloy phase or the Cu—Sn—Ni alloy phase and a silicon substrate (not illustrated). By this means a reaction between copper and a silicon substrate is suppressed and an electrode having low volume resistivity and superior adhesiveness can be formed.

While, on the back surface side, aluminum in an aluminum electrode paste composition forming a back surface collecting electrode 5 diffuses into the back surface of a semiconductor substrate 1 during sintering to form a p⁺ diffusion layer 7, thereby establishing an ohmic contact between the semiconductor substrate 1 and a back surface collecting electrode 5, and a back surface power output electrode 6.

As the second example of methods for forming a light receiving surface electrode 4, a back surface collecting electrode 5 and a back surface power output electrode 6, an aluminum electrode paste composition forming a back surface collecting electrode 5 is firstly printed, dried, and then sintered in the atmosphere at approx. 750° C. to 900° C. to complete a back surface collecting electrode 5; and then a paste composition for an electrode according to the present invention is printed on each of the light receiving surface side and the back surface side, dried, and then sintered in the atmosphere at approx. 450° C. to 650° C. to complete a light receiving surface electrode 4 and a back surface power output electrode 6.

This method is effective for the following case. Namely, a sintering temperature of 650° C. or less for sintering an aluminum electrode paste to form a back surface collecting electrode 5 may be, subject to a composition of an aluminum paste, insufficient for sintering the aluminum particle and diffusing in an adequate quantity into a semiconductor substrate 1, so that occasionally a p⁺ diffusion layer may not be formed sufficiently. In such a situation an adequate ohmic contact cannot be established on the back surface between a semiconductor substrate 1 and a back surface collecting electrode 5 and a back surface power output electrode 6, and the electricity generation performance of a photovoltaic cell element may be lowered. Consequently, it is preferable that a back surface collecting electrode 5 is firstly formed at a sintering temperature optimal to an aluminum electrode paste composition (for example, 750° C. to 900° C.), and then the paste composition for an electrode is printed, dried, and sinters at a relatively low temperature (450° C. to 650° C.) to form a light receiving surface electrode 4 and a back surface power output electrode 6.

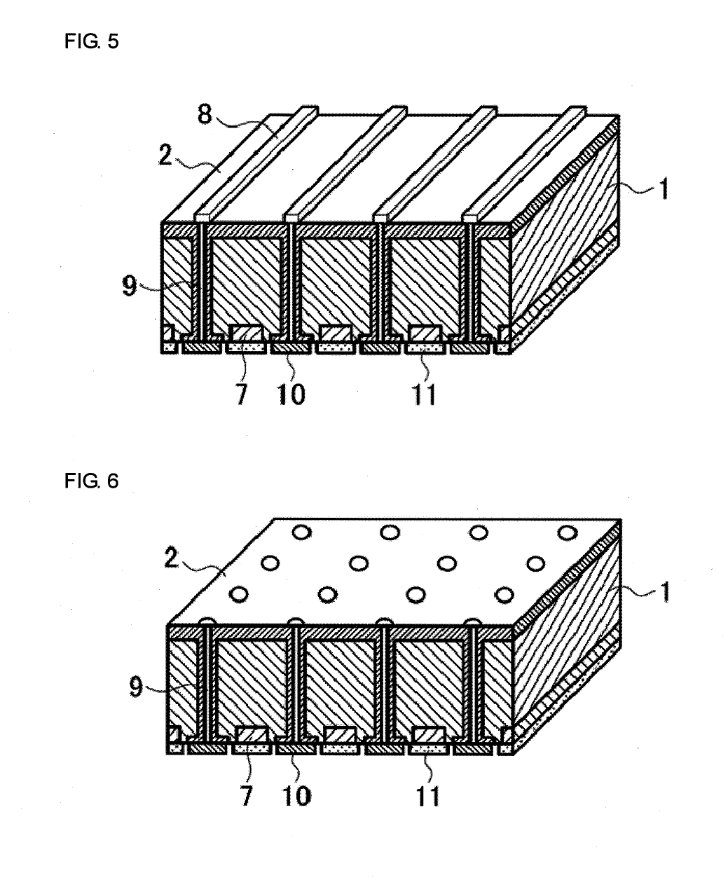

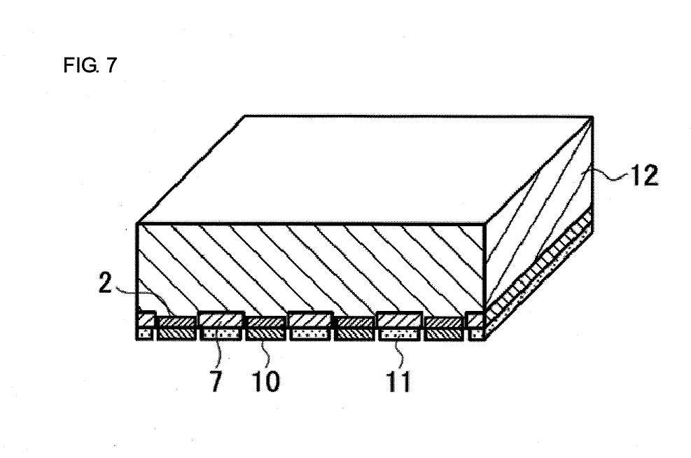

Further, a schematic plan view of the back surface side electrode structure common to a so-called back-contact type photovoltaic cell element as another embodiment of the present invention is shown in FIG. 4, and perspective views showing outlined structures of photovoltaic cell elements, which are different embodiments of a back-contact type photovoltaic cell element, in FIG. 5, FIG. 6 and FIG. 7 respectively. While, FIG. 5, FIG. 6 and FIG. 7 are perspective views along the AA cross-section in FIG. 4.

In a photovoltaic cell element having a structure shown in a perspective view of FIG. 5 through-holes are formed through a semiconductor substrate 1 penetrating both the light receiving surface side and the back surface side by laser drilling or etching. Further, on the light receiving surface side a texture (not illustrated) enhancing the light incidence efficiency is fabricated. Additionally are formed on the light receiving surface side an n⁺ diffusion layer 2 by means of an n type diffusion treatment and an antireflection film (not illustrated) on the n⁺ diffusion layer 2. They can be formed by the same process as for a conventional crystalline silicon type photovoltaic cell element.

Next, into the previously prepared through-holes a paste composition for an electrode according to the present invention is filled by means of a printing method or an ink jet method, and on the light receiving surface side similarly a paste composition for an electrode according to the present invention is printed in a grid form, to form a composition layer constituting a through-hole electrode 9 and a light receiving surface collecting electrode 8.

In this regard, with respect to pastes for filling and for printing, pastes with different compositions having the viscosity, etc. optimized to the respective processes are preferably utilized, but both filling and printing may be carried out by a paste with a single composition.

Meanwhile, on the back surface side, in order to prevent recombination of carriers an n⁺ diffusion layer 2 and a p⁺ diffusion layer 7 are formed. In this case, as an impurity element forming a p⁺ diffusion layer 7 boron (B) or aluminum (Al) is used. The p⁺ diffusion layer 7 may be formed for example by exercising a thermal diffusing treatment using B as a diffusion source in a production process of a photovoltaic cell element before forming the antireflection coating; or if aluminum is used it may be formed by printing and sintering an aluminum paste on the opposite surface side in the printing process.

On the back surface side as shown in a plan view of FIG. 4, back surface electrodes 10 and 11 are formed by printing a paste composition for an electrode according to the present invention in a stripe form on an n⁺ diffusion layer 2 and a p⁺ diffusion layer 7 respectively. If the p⁺ diffusion layer 7 is formed by an aluminum paste, back surface electrodes are so formed that the paste composition for an electrode is used only on the n⁺ diffusion layer 2 side.

Followed by drying and sintering in the atmosphere at approx. 450° C. to 900° C., a light receiving surface collecting electrode 8, a through-hole electrode 9, and back surface electrodes 10, 11 are completed. If an aluminum electrode is used for either of back surface electrodes as described above, from the perspectives of a sintering property of aluminum and a ohmic contact property between a back surface electrode and a p⁺ diffusion layer 7, an aluminum paste is printed and sintered to form either of the back surface electrodes beforehand, and then the paste composition for an electrode may be printed or filled and sintered to form a light receiving surface collecting electrode 8, a through-hole electrode 9, and the other back surface electrode.

A photovoltaic cell element having a structure shown in a perspective view of FIG. 6 can be produced identically with a photovoltaic cell element having a structure shown in a perspective view of FIG. 5, except that a light receiving surface collecting electrode is not formed. Namely, in a photovoltaic cell element having a structure shown in a perspective view of FIG. 6, a paste composition for an electrode according to the present invention can be used for a through-hole electrode 9 and back surface electrodes 10, 11.

Further, a photovoltaic cell element having a structure shown in a perspective view of FIG. 7 can be formed identically with a photovoltaic cell element having a structure shown in a perspective view of FIG. 5, except that an n-type silicon substrate is used as a basic semiconductor substrate, and a through-hole is not formed. Namely, in a photovoltaic cell element having a structure shown in a perspective view of FIG. 7, a paste composition for an electrode according to the present invention can be used for back surface electrodes 10, 11.

The application of the paste composition for an electrode is not limited to a photovoltaic cell electrode as described above, and it may be favorably applied also to electrode wiring and shield wiring for a plasma display, a ceramic capacitor, an antenna circuit, various sensor circuits, a heat radiating material for a semiconductor device, etc. Among them, it can be used favorably especially for forming an electrode on a substrate containing silicon.

<Photovoltaic Cell>

A photovoltaic cell according to the present invention is so constituted that at least one of the photovoltaic cell element is included and a wiring material is provided on an electrode of the photovoltaic cell element. A photovoltaic cell may be also so constituted that it includes according to need plural photovoltaic cell elements connected by means of a wiring material, and is encapsulated by an encapsulation material. There is no particular restriction on the wiring material and the encapsulation material, and any one may be selected from those used commonly in the art.

### EXAMPLES

Hereinbelow, the present invention will be described in detail with reference to Examples, but the present invention is not limited to these Examples. Further, unless otherwise specified, “parts” and “%” are based on mass.

### Example 1

### (a) Preparation of Paste Composition for Electrode

A phosphorus-containing copper alloy containing 7% by mass of phosphorus was prepared according to a conventional method, dissolved and pulverized by a water atomization process, followed by dying and classification. The classified powders were blended, and subjected to deoxigenation and dehydration treatments to yield a phosphorus-containing copper alloy particle containing 7% by mass of phosphorus. Meanwhile, the average particle diameter (D50%) of the phosphorus-containing copper alloy particle was 5.0 μm and the shape was approximately spherical.

The particle shape of the phosphorus-containing copper alloy particle was judged by observation with a scanning electron microscope (trade name: TM-1000, manufactured by Hitachi High-Technologies Corporation). The average diameter of the phosphorus-containing copper alloy particle was calculated with a laser diffraction average particle diameter analyzer (measurement wave length: 632 nm, trade name: LS 13 320, manufactured by Beckman Coulter, Inc.).

A glass (hereinafter occasionally abbreviated as “G01”) composed of silicon dioxide (SiO₂) 3 parts, lead oxide (PbO) 60 parts, boron oxide (B₂O₃) 18 parts, bismuth oxide (Bi₂O₃) 5 parts, aluminum oxide (Al₂O₃) 5 parts, and zinc oxide (ZnO) 9 parts was prepared. The obtained glass G01 had the softening point of 420° C., and the crystallization temperature was above 650° C.

Using the obtained glass G01 a glass G01 particle with the average particle diameter (D50%) of 2.5 μm was produced. The shape thereof was approximately spherical.

The glass particle shape was judged by observing with TM-1000 scanning electron microscope manufactured by Hitachi High-Technologies Corporation. The average particle diameter of the glass particle was calculated by using LS 13 320 Laser Diffraction Particle diameter Analyzer (measurement wavelength: 632 nm) manufactured by Beckman Coulter, Inc. The softening point of the glass particle was determined by the differential thermal (DTA) curve using DTG-60H TG/DTA Simultaneous Measuring Instrument manufactured by Shimadzu Corporation.

The obtained phosphorus-containing copper alloy particle 33.3 parts, a tin particle (Sn: average particle diameter (D50%) of 5.0 μm; purity of 99.9%) 22.8 parts, the glass G01 particle 22.8 parts, nickel particle (Ni: average particle diameter (D50%) of 5.0 μm; purity of 99.9%) 22.8 parts, diethylene glycol monobutylether (BC) 11.7 parts and ethyl polyacrylate (EPA) 2.2 parts were blended and mixed using an automatic mortar kneading machine to make a paste to prepare a paste composition 1 for an electrode.

### (b) Production of Photovoltaic Cell Element

A p-type semiconductor substrate with the thickness of 190 μm provided with an n⁺ diffusion layer, a texture and an antireflection coating (silicon nitride film) on the light receiving surface was prepared and a specimen in the size of 125 mm×125 mm was cut out therefrom. On the light receiving surface thereof the paste composition 1 for an electrode obtained as above was printed by a screen printing method to form the electrode pattern shown in FIG. 2. The electrode pattern was constituted of 150 μm-wide finger lines and 1.5 mm-wide bus bars, and the printing conditions (screen mesh size, printing speed, and printing pressure) were adjusted appropriately to obtain the layer thickness after sintering of 20 μm. The specimen was placed in an oven heated to 150° C. for 15 min to evaporate off the solvent.

Next, on the opposite surface to the light receiving surface (hereinafter, also referred to as “back surface”), the paste composition 1 for an electrode and an aluminum electrode paste were printed similarly as above by a screen printing method to form the electrode pattern shown in FIG. 3.

The pattern of the back surface power output electrode composed of the paste composition 1 for an electrode was constituted of 123 mm×5 mm printed at total 2 places. While, the printing conditions (screen mesh size, printing speed, and printing pressure) were adjusted appropriately to obtain the layer thickness of the back surface power output electrode after sintering of 20 μm. The aluminum electrode paste was printed on the whole surface outside the back surface power output electrode to form the back surface collecting electrode pattern. The printing conditions of the aluminum electrode paste were adjusted appropriately to obtain the layer thickness of the back surface collecting electrode after sintering of 30 μm. The specimen was placed in an oven heated to 150° C. for 15 min to evaporate off the solvent.

Next, a heat treatment (sintering) was conducted using a tunnel oven (1-line W/B conveyor tunnel furnace, by Noritake Co., Limited) in the atmosphere for the retention time of 10 sec at the maximum sintering temperature of 800° C. to yield a photovoltaic cell element 1 provided with the desired electrodes.

### Example 2

A photovoltaic cell element 2 was produced identically with Example 1, except that the sintering condition for forming an electrode was changed from 10 sec at the maximum temperature of 800° C. in Example 1 to 8 sec at the maximum temperature of 850° C.

### Example 3

A photovoltaic cell element 3 was produced by preparing a paste composition 3 for an electrode identically with Example 1, except that the phosphorus content of the phosphorus-containing copper alloy particle was changed from 7% by mass in Example 1 to 6% by mass.

### Example 4

A photovoltaic cell element 4 was produced by preparing a paste composition 4 for an electrode identically with Example 1, except that the phosphorus content of the phosphorus-containing copper alloy particle was changed from 7% by mass in Example 1 to 8% by mass.

### Example 5

A photovoltaic cell element 5 was produced by preparing a paste composition 5 for an electrode identically with Example 1, except that the sintering condition for forming an electrode was changed from 10 sec at the maximum temperature of 800° C. in Example 1 to 8 sec at the maximum temperature of 850° C.

### Example 6

A photovoltaic cell element 6 was produced by preparing a paste composition 6 for an electrode identically with Example 1, except that the average particle diameter (D50%) of the phosphorus-containing copper alloy particle was changed from 5.0 μm in Example 1 to 1.5 μm.

### Example 7

A photovoltaic cell element 7 was produced by preparing a paste composition 7 for an electrode identically with Example 1, except that the contents of the phosphorus-containing copper alloy particle, the tin-containing particle and the nickel-containing particle in Example 1 were changed to the content of the phosphorus-containing copper alloy particle of 36.5 parts, the content of the tin-containing particle of 25.4 parts, and the content of the nickel-containing particle of 16.4.

### Example 8

A photovoltaic cell element 8 was produced by preparing a paste composition 8 for an electrode identically with Example 1, except that the contents of the phosphorus-containing copper alloy particle, the tin-containing particle and the nickel-containing particle in Example 1 were changed to the content of the phosphorus-containing copper alloy particle of 46.5 parts, the content of the tin-containing particle of 9.4 parts, and the content of the nickel-containing particle of 22.4 parts.

### Example 9

A photovoltaic cell element 9 was produced by preparing a paste composition 9 for an electrode identically with Example 1, except that as the tin-containing particle instead of the tin particle (Sn) in Example 1a tin alloy particle composed of Sn-4Ag-0.5Cu (Sn alloy containing 4% by mass of Ag and 0.5% by mass of Cu) was used, and the average particle diameter thereof (D50%) of 8.0 μm was selected.

### Example 10

A photovoltaic cell element 10 was produced by preparing a paste composition 10 for an electrode identically with Example 1, except that as the nickel-containing particle instead of the nickel particle (Ni) in Example 1a tin alloy particle composed of Ni-60Cu (Ni alloy containing 60% by mass of Cu) was used, and the average particle diameter thereof (D50%) of 7.0 μm was selected.

### Example 11

A photovoltaic cell element 11 was produced by preparing a paste composition 11 for an electrode identically with Example 1, except that the average particle diameter (D50%) of the nickel-containing particle (Ni) was changed from 5.0 μm in Example 1 to 10.0 μm.

### Example 12

To the paste composition for an electrode in Example 1a silver particle (Ag; average particle diameter (D50%) 3.0 μm; purity 99.5%) was added. More specifically, a photovoltaic cell element 12 was produced by preparing a paste composition 12 for an electrode identically with Example 1, except that the contents of the respective ingredients were changed to 32.3 parts for the phosphorus-containing copper alloy particle, 21.8 parts for the tin particle, 20.2 parts for the nickel particle, 4.0 parts for the silver particle, 7.8 parts for the glass G01 particle, 11.7 parts for diethylene glycol monobutyl ether (BC), and 2.2 parts for ethyl polyacrylate (EPA).

### Example 13

In Example 1 the content of the glass G01 particle was changed. More specifically, a photovoltaic cell element 13 was produced by preparing a paste composition 13 for an electrode identically with Example 1, except that the contents of the respective ingredients were changed to 34.3 parts for the phosphorus-containing copper alloy particle, 23.7 parts for the tin particle, 23.2 parts for the nickel particle, 4.9 parts for the glass G01 particle, 11.7 parts for diethylene glycol monobutyl ether (BC), and 2.2 parts for ethyl polyacrylate (EPA).

### Example 14

A photovoltaic cell element 14 was produced by preparing a paste composition 14 for an electrode identically with Example 1, except that the composition of the glass particle was changed from the glass G01 in Example 1 to a glass G02 described below.

A glass G02 was prepare according to the composition of vanadium oxide (V₂O₅) 45 parts, phosphorus oxide (P₂O₅) 24.2 parts, barium oxide (BaO) 20.8 parts, antimony oxide (Sb₂O₃) 5 parts, and tungsten oxide (WO₃) 5 parts. The softening point of the glass G02 was 492° C., and the crystallization initiation temperature was above 650° C.

Using the obtained glass G02 a glass G02 particle with the average particle diameter (D50%) of 2.5 μm was prepared. The shape was approximately spherical.

### Example 15

In Example 1 the solvent was changed from diethylene glycol monobutyl ether to terpineol (Ter) and the resin was changed from poly(ethyl acrylate) to ethyl cellulose (EC) respectively. More specifically, a photovoltaic cell element 15 was produced by preparing a paste composition 15 for an electrode identically with Example 1, except that the contents of the respective ingredients were changed to 33.3 parts for the phosphorus-containing copper alloy particle, 22.8 parts for the tin particle, 22.2 parts for the nickel particle, 7.8 parts for the glass G01 particle, 13.5 parts for terpineol (Ter) and 0.4 parts for ethyl cellulose (EC).

### Examples 16 to 20

Paste compositions 16 to 20 for an electrode were prepared identically with Example 1, except that the phosphorus content, the average particle diameter (D50%) and the content of the phosphorus-containing copper alloy particle, the composition, the average particle diameter (D50%) and the content of the tin-containing particle, the composition, the average particle diameter (D50%) and the content of the nickel-containing particle, the content of the silver particle, the kind and the content of the glass particle, the kind and the content of the solvent, and the kind and the content of the resin in Example 1 were changed as shown in Table 1-1 and Table 1-2.

Next, using the respective obtained paste compositions 16 to 20 for an electrode, photovoltaic cell elements 16 to 20 provided with the desired electrodes were produced identically with Example 1 respectively, except that the temperature and the treatment time of the heat treatment were changed as shown in Table 1-1 and Table 1-2.

### Example 21

A p-type semiconductor substrate with the thickness of 190 μm provided with an n⁺ diffusion layer, a texture and an antireflection coating (silicon nitride film) on the light receiving surface was prepared and a specimen in the size of 125 mm×125 mm was cut out therefrom. Then on the back surface an aluminum electrode paste was printed to form a back surface collecting electrode pattern. The back surface collecting electrode pattern was printed on the whole surface outside the back surface power output electrode as shown in FIG. 3. While, the printing conditions of the aluminum electrode paste were adjusted appropriately to obtain the layer thickness of the back surface collecting electrode after sintering of 30 μm. The specimen was placed in an oven heated to 150° C. for 15 min to evaporate off the solvent.

Next, a heat treatment (sintering) was conducted using a tunnel oven (1-line W/B conveyor tunnel furnace, by Noritake Co., Limited) in the atmosphere for the retention time of 10 sec at the maximum sintering temperature of 800° C. to yield a back surface collecting electrode and a p⁺ diffusion layer.

Next, the paste composition 1 for an electrode obtained as above was printed to form electrode patterns as shown in FIG. 2 and FIG. 3. The electrode pattern on the light receiving surface was constituted of 150 μm-wide finger lines and 1.5 mm-wide bus bars, and the printing conditions (screen mesh size, printing speed, and printing pressure) were adjusted appropriately to obtain the layer thickness after sintering of 20 μm. The pattern of the back surface electrode was constituted of 123 mm×5 mm and printed at total 2 places with the layer thickness of 20 μm. The specimen was placed in an oven heated to 150° C. for 15 min to evaporate off the solvent.

Subsequently, the specimen was subjected to a heat treatment (sintering) using a tunnel oven (1-line W/B conveyor tunnel furnace, by Noritake Co., Limited) in the atmosphere for the retention time of 10 sec at the maximum sintering temperature of 650° C. to yield a photovoltaic cell element 21 provided with the desired electrodes.

### Example 22

A photovoltaic cell element 22 was produced identically with Example 21, except that the paste composition 3 for an electrode obtained as above was used for forming the light receiving surface electrode and the back surface power output electrode referred to in Example 21.

### Example 23

A photovoltaic cell element 23 was produced identically with Example 21, except that the paste composition 9 for an electrode obtained as above was used for forming the light receiving surface electrode and the back surface power output electrode referred to in Example 21, and that the sintering condition in forming the electrodes was changed from 10 sec at the maximum temperature of 650° C. to 10 sec at the maximum temperature of 620 sec.

### Example 24

Using the paste composition 1 for an electrode obtained as above, a photovoltaic cell element 24 having the structure as shown in FIG. 5 was produced. A specific production method will be described below. Firstly, through-holes with the diameter of 100 μm were bored in the p-type silicon substrate penetrating both the light receiving surface side and the back surface side by a laser drill. Further, on the light receiving surface side, a texture, an n⁺ diffusion layer, and an antireflection coating were formed successively. In this regard, the n⁺ diffusion layer was also formed in the through-holes, and on a part of the back surface respectively. Then the paste composition 1 for an electrode was filled in the preformed through-holes by an ink jet method and additionally printed on the light receiving surface side in a grid form.

On the other hand, on the back surface side using the paste composition 1 for an electrode the pattern shown in FIG. 4 was printed in a stripe form, thereby the paste composition for an electrode layer being printed below the through-holes. An aluminum electrode paste was printed on the region other than the composition for an electrode layer, thereby forming an aluminum electrode paste layer. The specimen was subjected to a heat treatment using a tunnel oven (1-line W/B conveyor tunnel furnace, by Noritake Co., Limited) in the atmosphere for the retention time of 10 sec at the maximum sintering temperature of 800° C. to yield a photovoltaic cell element 24 provided with the desired electrodes.

In this case, at a part applied with an aluminum electrode paste a p⁺ diffusion layer was formed by reason of diffusion of Al in a p-type silicon substrate by sintering.

### Example 25

A photovoltaic cell element 25 was produced identically with Example 24, except that the paste composition 1 for an electrode in Example 24 was changed to the paste composition 16 for an electrode obtained as above to form the light receiving surface collecting electrode, the through-hole electrode, and the back surface electrode.

### Example 26

A photovoltaic cell element 26 was produced identically with Example 24, except that the sintering condition in forming an electrode was changed from 10 sec at the maximum temperature of 800° C. in Example 24 to 8 sec at the maximum temperature of 850° C.

### Example 27

A photovoltaic cell element 27 was produced identically with Example 24, except that the paste composition 1 for an electrode in Example 24 was changed to the paste composition 9 for an electrode obtained as above to form the light receiving surface collecting electrode, the through-hole electrode, and the back surface electrode.

### Example 28

A paste composition 28 for an electrode was prepared identically with Example 1, except that the glass particle was changed from the glass G01 particle in Example 1 to a glass G03 particle.

Meanwhile, a glass G03 was prepared according to the composition of silicon dioxide (SiO₂) 13 parts, boron oxide (B₂O₃) 58 parts, zinc oxide (ZnO) 38 parts, aluminum oxide (Al₂O₃) 12 parts, and barium oxide (BaO) 12 parts. The softening point of the obtained glass G03 was 583° C., and the crystallization initiation temperature was above 650° C.

Using the obtained glass G03 a glass G03 particle with the average particle diameter (D50%) of 2.5 μm was obtained. The shape thereof was approximately spherical.

Then using the paste composition 28 for an electrode obtained as above a photovoltaic cell element 28 having the structure as shown in FIG. 6 was produced. The production method was identical with Examples 24 to 27 except that the light receiving surface electrode was not formed. As for the sintering condition was the retention time 10 sec at the maximum temperature of 800° C.

### Example 29

A photovoltaic cell element 29 was produced identically with Example 28, except that the sintering condition for forming an electrode was changed from 10 sec at the maximum temperature of 800° C. in Example 28 to 8 sec at the maximum temperature of 850° C.

### Example 30

Using the paste composition 28 for an electrode obtained as above a photovoltaic cell element 30 having the structure as shown in FIG. 7 was produced. The production method was identical with Example 24 except that an n-type silicon substrate was used as a basic substrate, and the light receiving surface electrode, the through-holes and the through-hole electrode were not formed. As for the sintering condition was the retention time 10 sec at the maximum temperature of 800° C.

### Example 31

A paste composition 31 for an electrode was prepared identically with Example 5, except that the glass particle was changed from the glass G01 particle in Example 9 to the glass G03 particle. Using the same a photovoltaic cell element 31 having the structure shown in FIG. 7 was produced identically with Example 30.

### Example 32

A paste composition 32 for an electrode was prepared identically with Example 16, except that the glass particle was changed from the glass G01 particle in Example 12 to the glass G03 particle. Using the same a photovoltaic cell element 32 having the structure shown in FIG. 7 was produced identically with Example 30.

### Comparative Example 1

A paste composition C1 for an electrode was prepared identically with Example 1, except that the phosphorus-containing copper alloy particle and the tin-containing particle in the preparation of a paste composition for an electrode in Example 1 were not used and changed to the composition of the respective ingredients as shown in Table 1-1 and Table 1-2.

A photovoltaic cell element C1 was produced identically with Example 1 except that the paste composition C1 for an electrode not containing a phosphorus-containing copper alloy particle and a tin-containing particle was used.

### Comparative Examples 2 to 4

In the preparation of the paste composition for an electrode in Example 1, paste compositions C2 to C4 for an electrode were prepared according to compositions shown in Table 1-1 and Table 1-2 using a phosphorus-containing copper alloy particle with the different phosphorus content, and without using a tin-containing particle and a nickel-containing particle.

Photovoltaic cell elements C2 to C4 were produced identically with Comparative Example 1 respectively, except that the respective paste compositions C2 to C4 for an electrode were used.

### Comparative Examples 5

A paste composition C5 for an electrode was prepared identically with Example 1, except that a copper particle (purity 99.5%; average particle diameter (D50%) 5.0 μm; content 33.3 parts) was used instead of a phosphorus-containing copper alloy particle used in the preparation of a paste composition for an electrode in Example 1, and the composition of the respective ingredients was modified as shown in Table 1-1 and Table 1-2.

A photovoltaic cell element C5 was produced identically with Comparative Example 1, except that the paste composition C5 for an electrode was used.

### Comparative Examples 6

A photovoltaic cell element C6 was produced identically with Example 24, except that the paste composition 1 for an electrode in Example 24 was changed to the paste composition C1 for an electrode obtained as above to form a light receiving surface collecting electrode, a through-hole electrode, and a back surface electrode were formed.

### Comparative Example 7

A photovoltaic cell element C7 was produced identically with Example 28, except that the paste composition 28 for an electrode in Example 28 was changed to the paste composition C1 for an electrode obtained as above.

### Comparative Example 8

A photovoltaic cell element C8 was produced identically with Example 30, except that the paste composition 28 for an electrode in Example 30 was changed to the paste composition C1 for an electrode obtained as above.

TABLE 1-1

| | Phosphorous-containing copper alloy particle | | | Tin-containing particle | | | Nickel-containing particle | | | Silver particle | | Glass particle | | | | | | |
|---|---|---|---|---|---|---|---|---|---|---|---|---|---|---|---|---|---|---|
| | | Particle | | | Particle | | | Particle | | Particle | | | Particle | | | | | |
| | | size | | | size | | | size | | size | | | size | | Solvent | | Resin | |
| | Phosphorous | (D50%) | Content | | (D50%) | Content | | (D50%) | Content | (D50%) | Content | | (D50%) | Content | | Content | | Content |
| Example | content (wt %) | (μm) | (part) | Composition | (μm) | (part) | Composition | (μm) | (part) | (μm) | (part) | Kind | (μm) | (part) | Kind | (part) | Kind | (part) |
| Example 1 | 7 | 5.0 | 33.3 | Sn | 5.0 | 22.8 | Ni | 5.0 | 22.2 | — | 0.0 | G01 | 2.5 | 7.8 | BC | 11.7 | EPA | 2.2 |
| Example 2 | 7 | 5.0 | 33.3 | Sn | 5.0 | 22.8 | Ni | 5.0 | 22.2 | | 0.0 | G01 | 2.5 | 7.8 | BC | 11.7 | EPA | 2.2 |
| Example 3 | 6 | 5.0 | 33.3 | Sn | 5.0 | 22.8 | Ni | 5.0 | 22.2 | — | 0.0 | G01 | 2.5 | 7.8 | BC | 11.7 | EPA | 2.2 |
| Example 4 | 8 | 5.0 | 33.3 | Sn | 5.0 | 22.8 | Ni | 5.0 | 22.2 | — | 0.0 | G01 | 2.5 | 7.8 | BC | 11.7 | EPA | 2.2 |
| Example 5 | 8 | 5.0 | 33.3 | Sn | 5.0 | 22.8 | Ni | 5.0 | 22.2 | — | 0.0 | G01 | 2.5 | 7.8 | BC | 11.7 | EPA | 2.2 |
| Example 6 | 7 | 1.5 | 33.3 | Sn | 5.0 | 22.8 | Ni | 5.0 | 22.2 | — | 0.0 | G01 | 2.5 | 7.8 | BC | 11.7 | EPA | 2.2 |
| Example 7 | 7 | 5.0 | 36.5 | Sn | 5.0 | 25.4 | Ni | 5.0 | 16.4 | — | 0.0 | G01 | 2.5 | 7.8 | BC | 11.7 | EPA | 2.2 |
| Example 8 | 7 | 5.0 | 46.5 | Sn | 5.0 | 9.4 | Ni | 5.0 | 22.4 | — | 0.0 | G01 | 2.5 | 7.8 | BC | 11.7 | EPA | 2.2 |
| Example 9 | 7 | 5.0 | 33.3 | Sn—4Ag—0.5Cu | 8.0 | 22.8 | Ni | 5.0 | 22.2 | — | 0.0 | G01 | 2.5 | 7.8 | BC | 11.7 | EPA | 2.2 |
| Example 10 | 7 | 5.0 | 33.3 | Sn | 8.0 | 22.8 | Ni—60Cu | 7.0 | 22.2 | — | 0.0 | G01 | 2.5 | 7.8 | BC | 11.7 | EPA | 2.2 |
| Example 11 | 7 | 5.0 | 33.3 | Sn | 5.0 | 22.8 | Ni | 10.0 | 22.2 | — | 0.0 | G01 | 2.5 | 7.8 | BC | 11.7 | EPA | 2.2 |
| Example 12 | 7 | 5.0 | 32.3 | Sn | 5.0 | 21.8 | Ni | 10.0 | 20.2 | 3.0 | 4.0 | G01 | 2.5 | 7.8 | BC | 11.7 | EPA | 2.2 |
| Example 13 | 7 | 5.0 | 34.3 | Sn | 5.0 | 23.7 | Ni | 5.0 | 23.2 | — | 0.0 | G01 | 2.5 | 4.9 | BC | 11.7 | EPA | 2.2 |
| Example 14 | 7 | 5.0 | 33.3 | Sn | 5.0 | 22.8 | Ni | 5.0 | 22.2 | — | 0.0 | G02 | 2.5 | 7.8 | BC | 11.7 | EPA | 2.2 |
| Example 15 | 7 | 5.0 | 33.3 | Sn | 5.0 | 22.8 | Ni | 5.0 | 22.2 | — | 0.0 | G01 | 2.5 | 7.8 | Ter | 13.5 | EC | 0.4 |
| Example 16 | 8 | 5.0 | 37.7 | Sn | 5.0 | 25.7 | Ni—6Cui—20Zn | 5.0 | 14.9 | — | 0.0 | G01 | 2.5 | 7.8 | BC | 11.7 | EPA | 2.2 |
| Example 17 | 7 | 10.0 | 32.1 | Sn—58Bi | 5.0 | 29.8 | Ni | 5.0 | 13.6 | 3.0 | 2.8 | G01 | 2.5 | 7.8 | BC | 11.7 | EPA | 2.2 |
| Example 18 | 6 | 5.0 | 37.4 | Sn | 7.0 | 19.8 | Ni | 5.0 | 23.4 | — | 0.0 | G02 | 1.7 | 5.5 | Ter | 13.5 | EC | 0.4 |
| Example 19 | 7 | 5.0 | 30.5 | Sn—4Ag—0.5Cu | 8.0 | 16.8 | Ni | 5.0 | 24.3 | 3.0 | 5.0 | G01 | 2.5 | 7.8 | BC | 13.0 | EPA | 2.6 |
| Example 20 | 7 | 1.5 | 40.5 | Sn | 3.0 | 20.9 | Ni | 5.0 | 20.8 | — | 0.0 | G01 | 1.7 | 3.9 | BC | 11.7 | EPA | 2.2 |
| Example 21 | 7 | 5.0 | 33.3 | Sn | 5.0 | 22.8 | Ni | 5.0 | 22.2 | — | 0.0 | G01 | 2.5 | 7.8 | BC | 11.7 | EPA | 2.2 |
| Example 22 | 6 | 5.0 | 33.3 | Sn | 5.0 | 22.8 | Ni | 5.0 | 22.2 | — | 0.0 | G01 | 2.5 | 7.8 | BC | 11.7 | EPA | 2.2 |
| Example 23 | 7 | 5.0 | 33.3 | Sn—4Ag—0.5Cu | 8.0 | 22.8 | Ni | 5.0 | 22.2 | — | 0.0 | G01 | 2.5 | 7.8 | BC | 11.7 | EPA | 2.2 |
| Example 24 | 7 | 5.0 | 33.3 | Sn | 5.0 | 22.8 | Ni | 5.0 | 22.2 | — | 0.0 | G01 | 2.5 | 7.8 | BC | 11.7 | EPA | 2.2 |
| Example 25 | 8 | 5.0 | 37.7 | Sn | 5.0 | 25.7 | Ni—6Cui—20Zn | 5.0 | 14.9 | — | 0.0 | G01 | 2.5 | 7.8 | BC | 11.7 | EPA | 2.2 |
| Example 26 | 7 | 5.0 | 33.3 | Sn | 5.0 | 22.8 | Ni | 5.0 | 22.2 | — | 0.0 | G01 | 2.5 | 7.8 | BC | 11.7 | EPA | 2.2 |
| Example 27 | 7 | 5.0 | 33.3 | Sn—4Ag—0.5Cu | 8.0 | 22.8 | Ni | 5.0 | 22.2 | — | 0.0 | G01 | 2.5 | 7.8 | BC | 11.7 | EPA | 2.2 |
| Example 28 | 7 | 5.0 | 33.3 | Sn | 5.0 | 22.8 | Ni | 5.0 | 22.2 | — | 0.0 | G03 | 2.5 | 7.8 | BC | 11.7 | EPA | 2.2 |
| Example 29 | 7 | 5.0 | 33.3 | Sn | 5.0 | 22.8 | Ni | 5.0 | 22.2 | — | 0.0 | G03 | 2.5 | 7.8 | BC | 11.7 | EPA | 2.2 |
| Example 30 | 7 | 5.0 | 33.3 | Sn | 5.0 | 22.8 | Ni | 5.0 | 22.2 | — | 0.0 | G03 | 2.5 | 7.8 | BC | 11.7 | EPA | 2.2 |
| Example 31 | 7 | 5.0 | 33.3 | Sn—4Ag—0.5Cu | 8.0 | 22.8 | Ni | 5.0 | 22.2 | — | 0.0 | G03 | 2.5 | 7.8 | BC | 11.7 | EPA | 2.2 |
| Example 32 | 8 | 5.0 | 37.7 | Sn | 5.0 | 25.7 | Ni—6Cui—20Zn | 5.0 | 14.9 | — | 0.0 | G03 | 2.5 | 7.8 | BC | 11.7 | EPA | 2.2 |
| Comparative | — | — | 0.0 | — | — | 0.0 | — | — | 0.0 | 3.0 | 78.3 | G01 | 2.5 | 7.8 | BC | 11.7 | EPA | 2.2 |
| Example 1 | | | | | | | | | | | | | | | | | | |
| Comparative | 0 | 5.0 | 78.3 | — | — | 0.0 | — | — | 0.0 | — | 0.0 | G01 | 2.5 | 7.8 | BC | 11.7 | EPA | 2.2 |
| Example 2 | | | | | | | | | | | | | | | | | | |
| Comparative | 1 | 5.0 | 78.3 | — | — | 0.0 | — | — | 0.0 | — | 0.0 | G01 | 2.5 | 7.8 | BC | 11.7 | EPA | 2.2 |
| Example 3 | | | | | | | | | | | | | | | | | | |
| Comparative | 7 | 5.0 | 78.3 | — | — | 0.0 | — | — | 0.0 | — | 0.0 | G01 | 2.5 | 7.8 | BC | 11.7 | EPA | 2.2 |
| Example 4 | | | | | | | | | | | | | | | | | | |
| Comparative | 0 | 5.0 | 33.3 | Sn | 5.0 | 22.8 | Ni | 5.0 | 22.2 | — | 0.0 | G01 | 2.5 | 7.8 | BC | 11.7 | EPA | 2.2 |
| Example 5 | | | | | | | | | | | | | | | | | | |
| Comparative | — | — | 0.0 | — | — | 0.0 | — | — | 0.0 | 3.0 | 78.3 | G01 | 2.5 | 7.8 | BC | 11.7 | EPA | 2.2 |
| Example 6 | | | | | | | | | | | | | | | | | | |
| Comparative | — | — | 0.0 | — | — | 0.0 | — | — | 0.0 | 3.0 | 81.4 | G01 | 2.5 | 4.1 | Ter | 14.1 | EC | 0.4 |
| Example 7 | | | | | | | | | | | | | | | | | | |
| Comparative | — | — | 0.0 | — | — | 0.0 | — | — | 0.0 | 3.0 | 81.4 | G01 | 2.5 | 4.1 | Ter | 14.1 | EC | 0.4 |
| Example 8 | | | | | | | | | | | | | | | | | | |

TABLE 1-2

| | | | | | | | | | | Sintering condition | |
|---|---|---|---|---|---|---|---|---|---|---|---|
| | | | | | | | | Sintering condition | | for preppared | |
| | | Applied electrode | | | | | | for single use | | paste composition | |
| | | Light | Light | | | | | of Al paste | | for electrode | |
| | | receiving | receiving | Back | | | | Maxi- | | Maxi- | |
| | | surface | surface | surface | | | | munm | | munm | |
| | | collect- | power | power | Through- | Back | With Al | temper- | Retention | temper- | Retention |
| | Photovoltaic | iong | output | output | hole | surface | electrode | ature | time | ature | time |
| Example | cell structure | electrode | electrode | electrode | electrode | electrode | only | (° C.) | (sec) | (° C.) | (sec) |
| Example 1 | Both surface | yes | yes | yes | no | no | no | — | — | 800 | 10 |
| | electrode | | | | | | | | | | |
| Example 2 | Both surface | yes | yes | yes | no | no | no | — | — | 850 | 8 |
| | electrode | | | | | | | | | | |
| Example 3 | Both surface | yes | yes | yes | no | no | no | — | — | 800 | 10 |
| | electrode | | | | | | | | | | |
| Example 4 | Both surface | yes | yes | yes | no | no | no | — | — | 800 | 10 |
| | electrode | | | | | | | | | | |
| Example 5 | Both surface | yes | yes | yes | no | no | no | — | — | 850 | 8 |
| | electrode | | | | | | | | | | |
| Example 6 | Both surface | yes | yes | yes | no | no | no | — | — | 800 | 10 |
| | electrode | | | | | | | | | | |
| Example 7 | Both surface | yes | yes | yes | no | no | no | — | — | 800 | 10 |
| | electrode | | | | | | | | | | |
| Example 8 | Both surface | yes | yes | yes | no | no | no | — | — | 800 | 10 |
| | electrode | | | | | | | | | | |
| Example 9 | Both surface | yes | yes | yes | no | no | no | — | — | 800 | 10 |
| | electrode | | | | | | | | | | |
| Example 10 | Both surface | yes | yes | yes | no | no | no | — | — | 800 | 10 |
| | electrode | | | | | | | | | | |
| Example 11 | Both surface | yes | yes | yes | no | no | no | — | — | 800 | 10 |
| | electrode | | | | | | | | | | |
| Example 12 | Both surface | yes | yes | yes | no | no | no | — | — | 800 | 10 |
| | electrode | | | | | | | | | | |
| Example 13 | Both surface | yes | yes | yes | no | no | no | — | — | 800 | 10 |
| | electrode | | | | | | | | | | |
| Example 14 | Both surface | yes | yes | yes | no | no | no | — | — | 800 | 10 |
| | electrode | | | | | | | | | | |
| Example 15 | Both surface | yes | yes | yes | no | no | no | — | — | 800 | 10 |
| | electrode | | | | | | | | | | |
| Example 16 | Both surface | yes | yes | yes | no | no | no | — | — | 800 | 10 |
| | electrode | | | | | | | | | | |
| Example 17 | Both surface | yes | yes | yes | no | no | no | — | — | 800 | 10 |
| | electrode | | | | | | | | | | |
| Example 18 | Both surface | yes | yes | yes | no | no | no | — | — | 750 | 12 |
| | electrode | | | | | | | | | | |
| Example 19 | Both surface | yes | yes | yes | no | no | no | — | — | 800 | 10 |
| | electrode | | | | | | | | | | |
| Example 20 | Both surface | yes | yes | yes | no | no | no | — | — | 850 | 8 |
| | electrode | | | | | | | | | | |
| Example 21 | Both surface | yes | yes | yes | no | no | yes | 800 | 10 | 650 | 10 |
| | electrode | | | | | | | | | | |
| Example 22 | Both surface | yes | yes | yes | no | no | yes | 800 | 10 | 650 | 10 |
| | electrode | | | | | | | | | | |
| Example 23 | Both surface | yes | yes | yes | no | no | yes | 800 | 10 | 620 | 10 |
| | electrode | | | | | | | | | | |
| Example 24 | Back contact | yes | no | no | yes | yes | no | — | — | 800 | 10 |
| Example 25 | Back contact | yes | no | no | yes | yes | no | — | — | 800 | 10 |
| Example 26 | Back contact | yes | no | no | yes | yes | no | — | — | 800 | 8 |
| Example 27 | Back contact | yes | no | no | yes | yes | no | — | — | 800 | 10 |
| Example 28 | Back contact | no | no | no | yes | yes | no | — | — | 800 | 10 |
| Example 29 | Back contact | no | no | no | yes | yes | no | — | — | 850 | 8 |
| Example 30 | Back contact | no | no | no | no | yes | no | — | — | 800 | 10 |
| Example 31 | Back contact | no | no | no | no | yes | no | — | — | 800 | 10 |
| Example 32 | Back contact | no | no | no | no | yes | no | — | — | 800 | 10 |
| Comparative | Back contact | ∘ | ∘ | ∘ | — | — | no | — | — | 800 | 10 |
| Comparative | Both surface | yes | yes | yes | no | no | no | — | — | 800 | 10 |
| Example 2 | electrode | | | | | | | | | | |
| Comparative | Both surface | yes | yes | yes | no | no | no | — | — | 800 | 10 |
| Example 3 | electrode | | | | | | | | | | |
| Comparative | Both surface | yes | yes | yes | no | no | no | — | — | 800 | 10 |
| Example 4 | electrode | | | | | | | | | | |
| Comparative | Both surface | yes | yes | yes | no | no | no | — | — | 800 | 10 |
| Example 5 | electrode | | | | | | | | | | |
| Comparative | Back contact | yes | no | no | yes | yes | no | — | — | 800 | 10 |
| Example 6 | | | | | | | | | | | |
| Comparative | Back contact | no | no | no | yes | yes | no | — | — | 800 | 10 |
| Example 7 | | | | | | | | | | | |
| Comparative | Back contact | no | no | no | no | yes | no | — | — | 800 | 10 |
| Example 8 | | | | | | | | | | | |

<Evaluation>

Evaluation of a produced solar cell element was carried out in a combination of an artificial sunlight of WXS-155S-10 (by Wacom Electric Co., Ltd.) and a current-voltage (I-V) analyzer I-V Curve Tracer MP-160 (by EKO Instruments Co., Ltd.). Jsc (short circuit current), Voc (open-circuit voltage), FF (fill factor), and Eff (conversion efficiency) representing the electricity generation performance of a solar cell were obtained by measurements according to JIS-C-8912, JIS-C-8913 and JIS-C-8914. The respective found values on a solar cell element with a double-surface electrode structure were reduced to relative values based on the found values for Comparative Example 1 (solar cell element C1) as 100.0 and shown in Table 2. In this regard, for Comparative Example 2 the evaluation was not possible due to high resistivity of the electrode caused by oxidation of the copper particle.

Further, a cross-section of a light-receiving surface electrode formed by baking a prepared paste composition for an electrode was observed by a scanning electron microscope Miniscope TM-1000 (by Hitachi, Ltd.) with the acceleration voltage of 15 kV, to examine existence or nonexistence of a Cu—Sn alloy phase, a Cu—Sn—Ni alloy phase, and an Sn—P—O glass phase in an electrode, as well as a formed location of a Sn—P—O glass phase. The results are also shown in Table 2.

TABLE 2

| | Electricity generation performance as photovoltaic cell | | | | Observation result of electrode cross-section structure | | | |
|---|---|---|---|---|---|---|---|---|
| | Jsc | Voc | F.F. | Eff (relative | Existence or | Existence or | Sn—P—O glass phase | |
| | (relative value) | (relative value) | (relative | value) | Nonexistence | Nonexistence | Existence | |
| | short circuit | open-circuit | value) | conversion | of Cu—Sn | of Cu—Sn—Ni | or Non- | |
| Examples | current | voltage | fill factor | efficiency | alloy phase | alloy phase | existence | Formed location |
| Example 1 | 100.8 | 100.3 | 99.8 | 100.2 | Nonexistent | Existent | Existent | Between Cu—Sn—Ni alloy |
| | | | | | | | | phase - Silicon substrate |
| Example 2 | 100.3 | 100.8 | 100.2 | 100.5 | Nonexistent | Existent | Existent | Between Cu—Sn—Ni alloy |
| | | | | | | | | phase - Silicon substrate |
| Example 3 | 99.8 | 98.9 | 99.2 | 98.4 | Nonexistent | Existent | Existent | Between Cu—Sn—Ni alloy |
| | | | | | | | | phase - Silicon substrate |
| Example 4 | 100.2 | 100.1 | 99.3 | 98.9 | Nonexistent | Existent | Existent | Between Cu—Sn—Ni alloy |
| | | | | | | | | phase - Silicon substrate |
| Example 5 | 100.7 | 100.3 | 101.5 | 101.7 | Nonexistent | Existent | Existent | Between Cu—Sn—Ni alloy |
| | | | | | | | | phase - Silicon substrate |
| Example 6 | 99.5 | 99.9 | 100.3 | 100.2 | Nonexistent | Existent | Existent | Between Cu—Sn—Ni alloy |
| | | | | | | | | phase - Silicon substrate |
| Example 7 | 99.3 | 98.4 | 98.1 | 97.9 | Nonexistent | Existent | Existent | Between Cu—Sn—Ni alloy |
| | | | | | | | | phase - Silicon substrate |
| Example 8 | 100.3 | 101.6 | 100.2 | 100.0 | Nonexistent | Existent | Existent | Between Cu—Sn—Ni alloy |
| | | | | | | | | phase - Silicon substrate |
| Example 9 | 102.3 | 100.3 | 100.9 | 100.5 | Nonexistent | Existent | Existent | Between Cu—Sn—Ni alloy |
| | | | | | | | | phase - Silicon substrate |
| Example 10 | 99.4 | 98.0 | 97.2 | 97.2 | Nonexistent | Existent | Existent | Between Cu—Sn—Ni alloy |
| | | | | | | | | phase - Silicon substrate |
| Example 11 | 99.0 | 98.7 | 100.0 | 99.2 | Nonexistent | Existent | Existent | Between Cu—Sn—Ni alloy |
| | | | | | | | | phase - Silicon substrate |
| Example 12 | 103.4 | 100.2 | 101.5 | 102.4 | Nonexistent | Existent | Existent | Between Cu—Sn—Ni alloy |
| | | | | | | | | phase - Silicon substrate |
| Example 13 | 99.9 | 100.4 | 101.0 | 100.4 | Nonexistent | Existent | Existent | Between Cu—Sn—Ni alloy |
| | | | | | | | | phase - Silicon substrate |
| Example 14 | 101.3 | 100.6 | 100.4 | 100.7 | Nonexistent | Existent | Existent | Between Cu—Sn—Ni alloy |
| | | | | | | | | phase - Silicon substrate |
| Example 15 | 100.2 | 99.8 | 99.8 | 99.7 | Nonexistent | Existent | Existent | Between Cu—Sn—Ni alloy |
| | | | | | | | | phase - Silicon substrate |
| Example 16 | 98.7 | 99.0 | 99.5 | 99.2 | Nonexistent | Existent | Existent | Between Cu—Sn—Ni alloy |
| | | | | | | | | phase - Silicon substrate |
| Example 17 | 98.7 | 97.9 | 98.0 | 97.1 | Nonexistent | Existent | Existent | Between Cu—Sn—Ni alloy |
| | | | | | | | | phase - Silicon substrate |
| Example 18 | 100.1 | 100.0 | 101.2 | 101.5 | Nonexistent | Existent | Existent | Between Cu—Sn—Ni alloy |
| | | | | | | | | phase - Silicon substrate |
| Example 19 | 102.4 | 100.0 | 101.9 | 101.6 | Nonexistent | Existent | Existent | Between Cu—Sn—Ni alloy |
| | | | | | | | | phase - Silicon substrate |
| Example 20 | 100.9 | 99.4 | 99.8 | 99.2 | Nonexistent | Existent | Existent | Between Cu—Sn—Ni alloy |
| | | | | | | | | phase - Silicon substrate |
| Example 21 | 100.2 | 100.3 | 100.1 | 99.8 | Existent | Existent | Existent | Between Cu—Sn alloy phase/ |
| | | | | | | | | Cu—Sn—Ni alloy phase - |
| | | | | | | | | Silicon substrate |
| Example 22 | 99.8 | 99.4 | 100.0 | 99.5 | Existent | Existent | Existent | Between Cu—Sn alloy phase/ |
| | | | | | | | | Cu—Sn—Ni alloy phase - |
| | | | | | | | | Silicon substrate |
| Example 23 | 101.9 | 100.9 | 100.5 | 100.9 | Existent | Existent | Existent | Between Cu—Sn alloy phase/ |
| | | | | | | | | Cu—Sn—Ni alloy phase - |
| | | | | | | | | Silicon substrate |
| Comparative | 100.0 | 100.0 | 100.0 | 100.0 | — | — | — | — |
| Example 1 | | | | | | | | |
| Comparative | — | — | — | — | Nonexistent | Nonexistent | Nonexistent | — |
| Example 2 | | | | | | | | |
| Comparative | 35.6 | 45.2 | 40.4 | 7.2 | Nonexistent | Nonexistent | Nonexistent | — |
| Example 3 | | | | | | | | |
| Comparative | 39.9 | 38.2 | 37.7 | 18.5 | Nonexistent | Nonexistent | Nonexistent | — |
| Example 4 | | | | | | | | |
| Comparative | 12.3 | 18.5 | 22.4 | 19.6 | Nonexistent | Nonexistent | Nonexistent | — |
| Example 5 | | | | | | | | |

Obvious from Table 2, in Comparative Examples 3 to 5 the electricity generation performance deteriorated compared to Comparative Example 1. The above was apparently caused by the following. In Comparative Example 4, since a tin-containing particle was not included, interdiffusion of a silicon substrate and copper took place during baking and the pn-junction quality in the substrate seemingly deteriorated. In Comparative Example 5, since a phosphorus-containing copper alloy particle was not used and pure copper (phosphorus content was 0% by mass) was used, the copper particle was oxidized during baking before reacting with a tin-containing particle and therefore a Cu—Sn alloy phase was not formed, and seemingly the electrode resistivity increased.

On the other hand, the electricity generation performances of the solar cell elements produced in Examples 1 to 23 were more or less same as the found value for the solar cell element according to Comparative Example 1. Especially, with respect to the solar cell elements 21 to 23, although paste compositions for an electrode were baked at a relatively low temperature (620 to 650° C.), high electricity generation performances were exhibited. As the results of structure observation, in the light-receiving surface electrodes a Cu—Sn—Ni alloy phase or both of a Cu—Sn—Ni alloy phase and a Cu—Sn, and an Sn—P—O glass phase were present and the Sn—P—O glass phase was formed between the Cu—Sn alloy phase and the Cu—Sn—Ni alloy phase and the silicon substrate.

Next, the respective found values for back-contact type solar cell elements having the structure of FIG. 5 were reduced to relative values based on the found values in Comparative Example 6 as 100.0, and shown in Table 3. Further, the observation result of a cross-section of a light-receiving surface electrode was also shown in Table 3.

TABLE 3

| | Electricity generation performance as photovoltaic cell | | | | Observation result of electrode cross-section structure | | | |
|---|---|---|---|---|---|---|---|---|
| | Jsc | Voc | F.F. | Eff | Existence or | Existence or | Sn—P—O glass phase | |
| | (relative value) | (relative value) | (relative | (relative value) | Nonexistence | Nonexistence | Existence | |
| | short circuit | open-circuit | value) | conversion | of Cu—Sn | of Cu—Sn—Ni | or Non- | |
| Examples | current | voltage | fill factor | efficiency | alloy phase | alloy phase | existence | Formed location |
| Example 24 | 100.2 | 100.1 | 100.3 | 100.7 | Nonexistent | Existent | Existent | Between Cu—Sn—Ni alloy |
| | | | | | | | | phase - Silicon substrate |
| Example 25 | 99.8 | 100.2 | 99.5 | 99.4 | Nonexistent | Existent | Existent | Between Cu—Sn—Ni alloy |
| | | | | | | | | phase - Silicon substrate |
| Example 26 | 100.3 | 101.0 | 100.4 | 100.4 | Nonexistent | Existent | Existent | Between Cu—Sn—Ni alloy |
| | | | | | | | | phase - Silicon substrate |
| Example 27 | 100.1 | 99.5 | 100.5 | 99.8 | Nonexistent | Existent | Existent | Between Cu—Sn—Ni alloy |
| | | | | | | | | phase - Silicon substrate |
| Comparative | 100.0 | 100.0 | 100.0 | 100.0 | — | — | — | — |
| Example 6 | | | | | | | | |

Obvious from Table 3, the electricity generation performances of the solar cell elements produced in Examples 24 to 27 were more or less same as the solar cell element according to Comparative Example 6. As the results of structure observation, in the light-receiving surface electrodes a Cu—Sn—Ni alloy phase and an Sn—P—O glass phase were present and the Sn—P—O glass phase was formed between the Cu—Sn—Ni alloy phase and the silicon substrate.

Next, the respective found values for back-contact type solar cell elements having the structure of FIG. 6 were reduced to relative values based on the found values in Comparative Example 7 as 100.0, and shown in Table 4. Further, the observation result of a cross-section of an electrode formed by baking a prepared paste composition for an electrode out of back surface electrodes was also shown in Table 4.

TABLE 4

| | Electricity generation performance as photovoltaic cell | | | | Observation result of electrode cross-section structure | | | |
|---|---|---|---|---|---|---|---|---|
| | Jsc | Voc | F.F. | Eff | Existence or | Existence or | Sn—P—O glass phase | |
| | (relative value) | (relative value) | (relative | (relative value) | Nonexistence | Nonexistence | Existence | |
| | short circuit | open-circuit | value) | conversion | of Cu—Sn | of Cu—Sn—Ni | or Non- | |
| Examples | current | voltage | fill factor | efficiency | alloy phase | alloy phase | existence | Formed location |
| Example 28 | 100.8 | 100.2 | 100.9 | 100.5 | Nonexistent | Existent | Existent | Between Cu—Sn—Ni alloy |
| | | | | | | | | phase - Silicon substrate |
| Example 29 | 99.4 | 98.7 | 98.2 | 99.0 | Nonexistent | Existent | Existent | Between Cu—Sn—Ni alloy |
| | | | | | | | | phase - Silicon substrate |
| Comparative | 100.0 | 100.0 | 100.0 | 100.0 | — | — | — | — |
| Example 7 | | | | | | | | |

Obvious from Table 4, the electricity generation performances of the solar cell elements produced in Examples 28 to 29 were more or less same as the solar cell element according to Comparative Example 7. As the results of structure observation, in an electrode formed by baking a prepared paste composition for an electrode out of back-side electrodes, a Cu—Sn—Ni alloy phase and an Sn—P—O glass phase were present and the Sn—P—O glass phase was formed between the Cu—Sn—Ni alloy phase and the silicon substrate.

Next, the respective found values for back-contact type solar cell elements having the structure of FIG. 7 were reduced to relative values based on the found values in Comparative Example 8 as 100.0, and shown in Table 5. Further, the observation result of a cross-section of an electrode formed by baking a prepared paste composition for an electrode among back surface electrodes was also shown in Table 5.

TABLE 5

| | Electricity generation performance as photovoltaic cell | | | | Observation result of electrode cross-section structure | | | |
|---|---|---|---|---|---|---|---|---|
| | Jsc | Voc | F.F. | Eff | Existence or | Existence or | Sn—P—O glass phase | |
| | (relative value) | (relative value) | (relative | (relative value) | Nonexistence | Nonexistence | Existence | |
| | short circuit | open-circuit | value) | conversion | of Cu—Sn | of Cu—Sn—Ni | or Non- | |
| Examples | current | voltage | fill factor | efficiency | alloy phase | alloy phase | existence | Formed location |
| Example 30 | 100.2 | 100.4 | 100.8 | 100.4 | Nonexistent | Existent | Existent | Between Cu—Sn—Ni alloy |
| | | | | | | | | phase - Silicon substrate |
| Example 31 | 103.1 | 100.4 | 101.3 | 100.9 | Nonexistent | Existent | Existent | Between Cu—Sn—Ni alloy |
| | | | | | | | | phase - Silicon substrate |
| Example 32 | 99.2 | 98.9 | 98.7 | 98.9 | Nonexistent | Existent | Existent | Between Cu—Sn—Ni alloy |
| | | | | | | | | phase - Silicon substrate |
| Comparative | 100.0 | 100.0 | 100.0 | 100.0 | — | — | — | — |
| Example 8 | | | | | | | | |

The electricity generation performances of the solar cell elements produced in Examples 30 to 32 were more or less same as the solar cell element according to Comparative Example 8. As the results of structure observation, in an electrode formed by baking a prepared paste composition for an electrode out of back-side electrodes, a Cu—Sn—Ni alloy phase and an Sn—P—O glass phase were present and the Sn—P—O glass phase was formed between the Cu—Sn—Ni alloy phase and the silicon substrate.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

All publications, patent applications, and technical standards mentioned in this specification are herein incorporated by reference to the same extent as if each individual publication, patent application, or technical standard was specifically and individually indicated to be incorporated by reference.

1. A paste composition for an electrode comprising a phosphorus-containing copper alloy particle, a tin-containing particle, a nickel-containing particle, a glass particle, a solvent, and a resin.

2. The paste composition for an electrode according to claim 1, wherein the phosphorus content of the phosphorus-containing copper alloy particle is from 6% by mass to 8% by mass.

3. The paste composition for an electrode according to claim 1, wherein the tin-containing particle is at least one selected from the group consisting of a tin particle and a tin alloy particle having a tin content of 1% by mass or more.

4. The paste composition for an electrode according to claim 1, wherein the nickel-containing particle is at least one selected from the group consisting of a nickel particle and a nickel alloy particle having a tin content of 1% by mass or more.

5. The paste composition for an electrode according to claim 1, wherein the glass particle has a glass softening point of 650° C. or less and a crystallization initiation temperature of more than 650° C.

6. The paste composition for an electrode according to claim 1, wherein the content of the tin-containing particle is from 5% by mass to 70% by mass when the total content of the phosphorus-containing copper alloy particle, the tin-containing particle, and the nickel-containing particle is 100% by mass.

7. The paste composition for an electrode according to claim 1, wherein the content of the nickel-containing particle is from 10% by mass to 60% by mass when the total content of the phosphorus-containing copper alloy particle, the tin-containing particle, and the nickel-containing particle is 100% by mass.

8. The paste composition for an electrode according to claim 1, wherein the total content of the phosphorus-containing copper alloy particle, the tin-containing particle, and the nickel-containing particle is from 70% by mass to 94% by mass, the content of the glass particle is from 0.1% by mass to 10% by mass, and the total content of the solvent and the resin is from 3% by mass to 29.9% by mass.

9. The paste composition for an electrode according to claim 1, further comprising a silver particle.

10. The paste composition for an electrode according to claim 9, wherein the content of the silver particle is from 0.1% by mass to 10% by mass when the total content of the phosphorus-containing copper alloy particle, the tin-containing particle, the nickel-containing particle and the silver particle is 100% by mass.

11. The paste composition for an electrode according to claim 9, wherein the total content of the phosphorus-containing copper alloy particle, the tin-containing particle, the nickel-containing particle and the silver particle is from 70% by mass to 94% by mass, the content of the glass particle is from 0.1% by mass to 10% by mass, and the total content of the solvent and the resin is from 3% by mass to 29.9% by mass.

12. A photovoltaic cell element, comprising a silicon substrate having a pn-junction, and an electrode that is a sintered material of the paste composition for an electrode according to claim 1 and that has been applied on to the silicon substrate.

13. The photovoltaic cell element according to claim 12, wherein the electrode comprises a Cu—Sn—Ni alloy phase and an Sn—P—O glass phase.

14. The photovoltaic cell element according to claim 13, wherein the Sn—P—O glass phase is disposed between the Cu—Sn—Ni alloy phase and the silicon substrate.

15. A photovoltaic cell, comprising the photovoltaic cell element according to claim 12 and a wiring material disposed on the electrode of the photovoltaic cell element.
